(19) United States
(12) Patent Application Publication
(10) Pub. No.: US 2024/0284687 A1
(43) Pub. Date: Aug. 22, 2024

(54) MEMORY STRUCTURES HAVING A SINGLE ACCESS TRANSISTOR FOR MULTIPLE MEMORY DEVICES

(71) Applicant: International Business Machines Corporation, Armonk, NY (US)

(72) Inventors: Min Gyu Sung, Latham, NY (US); Julien Frougier, Albany, NY (US); Ruilong Xie, Niskayuna, NY (US); Chanro Park, Clifton Park, NY (US); Juntao Li, Cohoes, NY (US)

(21) Appl. No.: 18/112,020

(22) Filed: Feb. 21, 2023

(51) Int. Cl. H10B 99/00

(52) U.S. Cl. CPC H10B 99/22; H10B 99/10

(57) ABSTRACT

A semiconductor structure includes an access transistor, a first memory device connected to a first side of the access transistor, and a second memory device connected to a second side of the access transistor. In some embodiments, the first memory device is connected to a first end of a first source/drain region of the access transistor and the second memory device is connected to a second end of the first source/drain region of the access transistor. In other embodiments, the first memory device is connected to a first source/drain region of the access transistor and the second memory device is connected to a second source/drain region of the access transistor.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. As memory density increases, the need for new memory technology other than dynamic random access memory (DRAM) is needed. DRAM technology scaling is facing a wall due to various problems such as retention time. Emerging memory devices store data as resistance values. For example, phase change memory (PCM), magnetic random access memory (MRAM), spin-torque-transfer magnetic random access memory (STT-MRAM), and resistive random access memory (ReRAM or RRAM) use variations of resistance values to store data.

### SUMMARY

Embodiments of the invention provide techniques for forming memory structures having a single access transistor for multiple memory devices.

In one embodiment, a semiconductor structure includes an access transistor, a first memory device connected to a first side of the access transistor, and a second memory device connected to a second side of the access transistor. The first memory device is connected to a first end of a first source/drain region of the access transistor and the second memory device is connected to a second end of the first source/drain region of the access transistor.

In another embodiment, a semiconductor structure includes an access transistor, a first memory device connected to a first side of the access transistor, and a second memory device connected to a second side of the access transistor. The first memory device is connected to a first source/drain region of the access transistor and the second memory device is connected to a second source/drain region of the access transistor.

In another embodiment, an integrated circuit includes a memory structure including an access transistor, a first memory device connected to a first side of the access transistor, and a second memory device connected to a second side of the access transistor. The first memory device and the second memory device are each connected to an end of at least one source/drain region of the access transistor.

These and other features and advantages of embodiments described herein will become more apparent from the accompanying drawings and the following detailed description.

### BRIEF DESCRIPTION OF THE DRAWINGS

FIG. 1 shows a side cross-sectional view of a structure following formation of a nanosheet stack over a substrate, according to an embodiment of the invention.

FIG. 2 shows a side cross-sectional view of the FIG. 1 structure following patterning of the nanosheet stack, according to an embodiment of the invention.

FIG. 3 shows a side cross-sectional view of the FIG. 2 structure following formation of shallow trench isolation regions, according to an embodiment of the invention.

FIG. 4 shows a side cross-sectional view of the FIG. 3 structure following patterning of dummy gate structures, according to an embodiment of the invention.

FIG. 5 shows a side cross-sectional view of the FIG. 4 structure following removal of a sacrificial layer, according to an embodiment of the invention.

FIG. 6 shows a side cross-sectional view of the FIG. 5 structure following deposition of a spacer, according to an embodiment of the invention.

FIG. 7 shows a side cross-sectional view of the FIG. 6 structure following etch-back of the nanosheet stack, according to an embodiment of the invention.

FIG. 8 shows a side cross-sectional view of the FIG. 7 structure following formation of inner spacers, according to an embodiment of the invention.

FIG. 9 shows a side cross-sectional view of the FIG. 8 structure following formation of source/drain epitaxial layers, according to an embodiment of the invention.

FIG. 10 shows a side cross-sectional view of the FIG. 9 structure following formation of an interlayer dielectric, replacement metal gate processing, and formation of metal trenches, according to an embodiment of the invention.

FIG. 11 shows a side cross-sectional view of the FIG. 10 structure following formation of a back-end-of-line structure including a memory cell, according to an embodiment of the invention.

FIG. 12 shows a side cross-sectional view of the FIG. 11 structure following a wafer flip, according to an embodiment of the invention.

FIG. 13 shows a side cross-sectional view of the FIG. 12 structure following removal of the substrate and formation of an interlayer dielectric layer, according to an embodiment of the invention.

FIG. 14 shows a side cross-sectional view of the FIG. 13 structure following contact formation, according to an embodiment of the invention.

FIG. 15 shows a side cross-sectional view of the FIG. 14 structure following formation of another back-end-of-line structure including another memory cell, according to an embodiment of the invention.

FIG. 16A shows a current path in the FIG. 15 structure for a first one of the memory cells, according to an embodiment of the invention.

FIG. 16B shows a current path in the FIG. 15 structure for a second one of the memory cells, according to an embodiment of the invention.

FIG. 16C shows a detailed view of the memory cells including a selector device, according to an embodiment of the invention.

FIG. 16D shows a plot of operation of the selector device of the memory cells, according to an embodiment of the invention.

FIG. 17 shows a side cross-sectional view of the FIG. 9 structure following patterning of an organic planarization layer, according to an embodiment of the invention.

FIG. 18 shows a side cross-sectional view of the FIG. 17 structure following recess of one of the source/drain epitaxial layers, according to an embodiment of the invention.

FIG. 19 shows a side cross-sectional view of the FIG. 18 structure following removal of the organic planarization layer, according to an embodiment of the invention.

FIG. 20 shows a side cross-sectional view of the FIG. 19 structure following formation of a liner, according to an embodiment of the invention.

FIG. 21 shows a side cross-sectional view of the FIG. 20 structure following formation of an organic planarization layer, according to an embodiment of the invention.

FIG. 22 shows a side cross-sectional view of the FIG. 21 structure following recess of the organic planarization layer, according to an embodiment of the invention.

FIG. 23 shows a side cross-sectional view of the FIG. 22 structure following removal of portions of the liner, according to an embodiment of the invention.

FIG. 24 shows a side cross-sectional view of the FIG. 23 structure following removal of the organic planarization layer, according to an embodiment of the invention.

FIG. 25 shows a side cross-sectional view of the FIG. 24 structure following formation of source/drain epitaxial layers, according to an embodiment of the invention.

FIG. 26 shows a side cross-sectional view of the FIG. 25 structure following formation of an interlayer dielectric, replacement metal gate processing, and formation of metal trenches, according to an embodiment of the invention.

FIG. 27 shows a side cross-sectional view of the FIG. 26 structure following formation of a back-end-of-line structure including a memory cell, according to an embodiment of the invention.

FIG. 28 shows a side cross-sectional view of the FIG. 27 structure following a wafer flip, according to an embodiment of the invention.

FIG. 29 shows a side cross-sectional view of the FIG. 28 structure following removal of the substrate and formation of an interlayer dielectric layer, according to an embodiment of the invention.

FIG. 30 shows a side cross-sectional view of the FIG. 29 structure following contact formation, according to an embodiment of the invention.

FIG. 31 shows a side cross-sectional view of the FIG. 30 structure following formation of another back-end-of-line structure including additional memory cells, according to an embodiment of the invention.

FIG. 32A shows a current path in the FIG. 31 structure for a first one of the memory cells, according to an embodiment of the invention.

FIG. 32B shows a current path in the FIG. 31 structure for a second one of the memory cells, according to an embodiment of the invention.

FIG. 32C shows a current path in the FIG. 31 structure for a third one of the memory cells, according to an embodiment of the invention.

FIG. 33 shows a side cross-sectional view of a vertical transistor structure, according to an embodiment of the invention.

FIG. 34A shows a side cross-sectional view of the FIG. 33 following formation of a back-end-of-line structure including a memory cell with a selector device and an additional selector device, according to an embodiment of the invention.

FIG. 34B shows a detailed view of the memory cell with the selector device, according to an embodiment of the invention.

FIG. 35 shows a side cross-sectional view of the FIG. 34A structure following formation of another back-end-of-line structure including another memory cell with a selector device and another additional selector device, according to an embodiment of the invention.

FIG. 36A shows a current path for programming and sensing of a first one of the memory cells in the FIG. 35 structure, according to an embodiment of the invention.

FIG. 36B shows a plot of two-level resistance in programming and sensing for the first memory cell in the FIG. 35 structure, according to an embodiment of the invention.

FIG. 36C shows a current path for programming and sensing of a second one of the memory cells in the FIG. 35 structure, according to an embodiment of the invention.

FIG. 36D shows a plot of two-level resistance in programming and sensing for the second memory cell in the FIG. 35 structure, according to an embodiment of the invention.

FIG. 36E shows a current path for combined sensing of the first and second memory cells in the FIG. 35 structure, according to an embodiment of the invention.

FIG. 36F shows a plot of four-level resistance in combined sensing of the first and second memory cells in the FIG. 35 structure, according to an embodiment of the invention.

FIG. 36G shows a plot of resistances for a multiple-state memory structure including the first and second memory cells of the FIG. 35 structure, according to an embodiment of the invention.

FIG. 36H shows a plot of states for the multiple-state memory structure including the first and second memory cells of the FIG. 35 structure, according to an embodiment of the invention.

FIG. 36I shows a current path for logic operation of the FIG. 35 structure, according to an embodiment of the invention.

FIG. 37 shows a structure including a vertical transistor, a first back-end-of-line structure including a memory cell with a selector device and another selector device, and a second back-end-of-line structure including a capacitor, according to an embodiment of the invention.

FIG. 38A shows a current path for programming and sensing of the memory cell of the FIG. 37 structure, according to an embodiment of the invention.

FIG. 38B shows a current path for programming and sensing of the capacitor of the FIG. 37 structure, according to an embodiment of the invention.

FIG. 38C shows a current path for logic operation of the FIG. 37 structure, according to an embodiment of the invention.

FIG. 39 depicts an integrated circuit including one or more memory structures having a single access transistor for multiple memory cells, according to an embodiment of the invention.

### DETAILED DESCRIPTION

Illustrative embodiments of the invention may be described herein in the context of illustrative methods for forming memory structures with a single access transistor for multiple memory devices, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheet channels may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves removing sacrificial layers, which may be formed of silicon germanium (SiGe), between sheets of channel material, which may be formed of silicon (Si).

System memory, also referred to as random access memory, may utilize access transistors for memory cells, where each access transistor is used for a single memory cell. The memory cells may be capacitor-based in dynamic random access memory (DRAM) or may be variable memory cells such as magnetoresistive random access memory (MRAM), phase-change random access memory (PCRAM), resistive random access memory (RRAM), ferroelectric random access memory (FeRAM), etc. The use of one access transistor for each memory cell incurs an area penalty. For example, an access transistor may have source/drain regions coupled to a bitline and a storage capacitor, with a gate of the access transistor being coupled to a wordline. In some cases, a memory cell may implement a one transistor one resistor (1T1R) structure, with an access transistor having source/drain regions coupled to a source line and a bitline via a resistive element (e.g., an RRAM structure such as a metal-insulator-metal (MIM) stack), with a gate of the access transistor again being coupled to a wordline. NAND flash memory may have an access transistor for multiple memory cells, but NAND flash memory is not suitable for use as system memory.

Conventional approaches utilize a one transistor-one memory cell configuration (e.g., there is one-to-one relationship between access transistors and memory cells). In illustrative embodiments, a novel structure is provided which enables one transistor-multiple memory cell configurations (e.g., where there is a one-to-multiple relationship between access transistors and memory cells). The one transistor-multiple memory cell configuration may be a one transistor-two memory cell configuration with: one transistor and two resistive memory cells (1T-2R); one transistor, one capacitive memory cell and one resistive memory cell (1T-1C/1R); or one transistor and two capacitive memory cells (1T-2C). The one transistor-multiple memory cell configuration may alternatively be a one transistor-three memory cell configuration with: one transistor and three resistive memory cells (1T-3R); one transistor, two resistive memory cells and one capacitive memory cell (1T-2R/1C); one transistor and three capacitive memory cells (1T-3C); or one transistor, two capacitive memory cells and one resistive memory cell (1T-2C/1R). Advantageously, such one transistor-multiple memory cell configurations can provide higher memory cell density for system memory applications.

In some embodiments, a semiconductor structure includes a transistor (e.g., an access transistor) having a given source/drain epitaxial layer that connects to a terminal of a first memory cell which is integrated “above” the transistor (e.g., a top side of the transistor). The given source/drain epitaxial layer also extends to the other side of the transistor (e.g., a back side of the transistor) and connects to a terminal of a second memory cell. The first and second memory cells can be any combination of capacitor-based memory and resistive-based memory (e.g., including but not limited to RRAM, MRAM, STTRAM, FeRAM, and PCRAM).

The semiconductor structure may be formed by forming front-end-of-line (FEOL) transistors (e.g., including one or more access transistors for memory cells). The FEOL transistors may comprise gate-all-around (GAA) field-effect transistor (FET) structures, such as nanosheet transistor structures. It should be noted, however, that other types of transistor structures may be used if desired, such as planar gate transistor structures, FinFET structures, etc. Embedded memory cells (e.g., capacitor-based and/or resistive-based memory) are then formed “above” the FEOL transistors in a back-end-of-line (BEOL) region. Back side power delivery network (BSPDN) formation is then performed, which includes performing a wafer flip and planarization (e.g., using chemical mechanical planarization (CMP) or other suitable processing) down to shallow trench isolation (STI) regions. A substrate is then removed and replaced with an interlayer dielectric (ILD) layer, in which additional embedded memory cells (e.g., capacitor-based and/or resistive-based memory) are formed. Formation of the BSPDN is then completed.

In other embodiments, a semiconductor structure includes a transistor (e.g., an access transistor) having a first source/drain epitaxial layer that connects to a terminal of a first memory cell which is integrated “above” the transistor (e.g., a top side of the transistor). The first source/drain epitaxial layer also extends to the other side of the transistor (e.g., to a back side of the transistor), and connects to a terminal of a second memory cell. A second source/drain epitaxial layer also extends between the top and back sides of the transistor, but has a vertical isolation layer disposed therein enabling one side of the second source/drain epitaxial layer to be connected to a terminal of a third memory cell. The first, second and third memory cells can be any combination of capacitor-based memory and resistive-based memory (e.g., including but not limited to RRAM, MRAM, STTRAM, FeRAM, and PCRAM).

The semiconductor structure may be formed by forming FEOL transistors (e.g., including one or more access transistors for memory cells). The FEOL transistors may comprise GAA FET structures, such as nanosheet transistor structures. It should be noted, however, that other types of transistor structures may be used if desired, such as planar gate transistor structures, FinFET structures, etc. A vertical isolation layer is then formed on one side (e.g., in one of the two source/drain epitaxial layers that nanosheet channels of a nanosheet transistor connect to). Embedded memory cells (e.g., capacitor-based and/or resistive-based memory) are then formed “above” the FEOL transistors in a BEOL region. BSPDN formation is then performed, which includes performing a wafer flip and planarization (e.g., using CMP or other suitable processing) down to STI regions. A substrate is then removed and replaced with an ILD layer, in which additional embedded memory cells (e.g., capacitor-based and/or resistive-based memory) are formed. Formation of the BSPDN is then completed.

The one transistor-multiple memory cell configurations may also be used to enable multi-level memory devices to be formed without an area penalty. Memory cell sizes include planar or saddle transistor structures for 8F² and 6F² cell sizes, where “F” denotes feature size which is half the pitch size (e.g., F=pitch/2). Vertical channel transistors may be used to enable 4F² memory cell sizes. The one transistor-multiple memory cell configuration may include at least one memory cell or component which is located on the “top” of a vertical access transistor and at least one memory cell or component which is located on the “bottom” of the vertical access transistor.

Advantageously, such a configuration does not incur an area penalty and enables a multi-level memory cell structure.

In some embodiments, a semiconductor structure includes an access transistor which is a vertical transistor. A first memory cell (e.g., an embedded memory cell which may be capacitor-based or resistive-based memory) is formed “above” the access transistor vertically, and a second memory cell (e.g., an embedded memory cell which may be capacitor-based or resistive-based memory) is formed underneath or “below” the access transistor vertically. The memory cells and circuits may have associated selection devices. The semiconductor structure may thus provide a 1T-2R or 1T-1C/1R structure.

The semiconductor structure may be formed by forming FEOL vertical transistors (e.g., including one or more access transistors for memory cells), and forming embedded memory cells (e.g., capacitor-based or resistive-based memory) above the FEOL vertical transistors in a BEOL region. BSPDN formation is then initiated, which includes performing a wafer flip and planarization (e.g., using CMP or other suitable processing) to remove a substrate. Embedded memory cells (e.g., capacitor-based or resistive-based memory) and selector devices are then formed in another BEOL region. Multi-level programming and sensing may then be performed using combinations of the embedded memory cells formed above and below the FEOL vertical transistors.

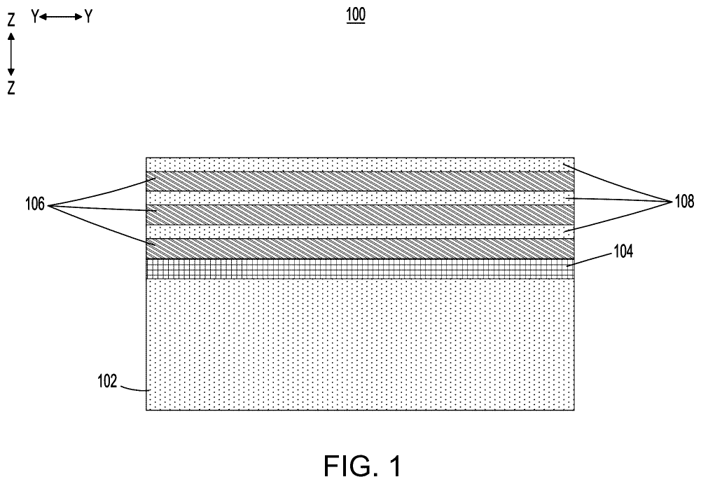

Process flows for forming memory structures where a single access transistor is used for multiple memory cells will now be described with respect to FIGS. 1-38C.

FIG. 1 shows a side cross-sectional view 100 of a structure following formation of a nanosheet stack over a substrate 102. The substrate 102 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc.

A nanosheet stack is formed over the substrate 102, where the nanosheets include sacrificial layers 104 and 106 and nanosheet channel layers 108. The sacrificial layer 104 may be formed of a first sacrificial material and the sacrificial layers 106 may be formed of a second sacrificial material different than the first sacrificial material, such that the sacrificial layer 104 may be etched or otherwise removed selected to the sacrificial layers 106. In some embodiments, both the sacrificial layer 104 and the sacrificial layers 106 are formed of SiGe, but with different percentages of Ge. For example, the sacrificial layer 104 may have a relatively higher percentage of Ge (e.g., 55% Ge), and the sacrificial layers 106 may have a relatively lower percentage of Ge (e.g., 30% Ge). Other combinations of different sacrificial materials may be used in other embodiments. The sacrificial layers 104 and 106 may each have a thickness (in direction Z) in the range of 6-15 nm.

The nanosheet channel layers 108 may be formed of Si or another suitable material (e.g., a material similar to that used for the substrate 102). Each of the nanosheet channel layers 108 may have a thickness (in direction Z) in the range of 4-10 nm.

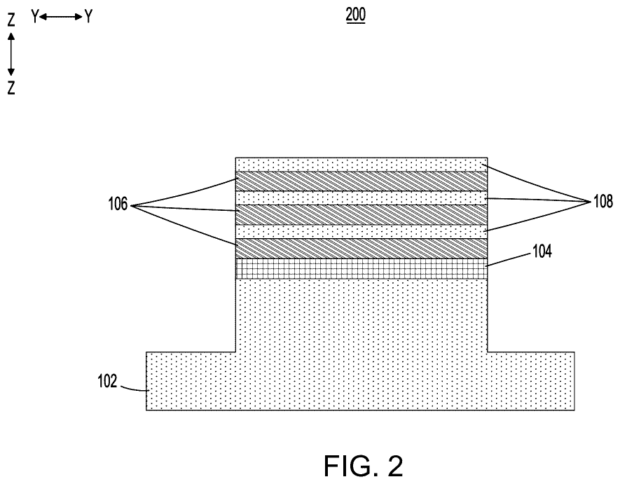

FIG. 2 shows a side cross-sectional view 200 of the FIG. 1 structure following patterning of the nanosheet stack. The nanosheet stack may be patterned by forming a hard mask (HM) layer over a top of the nanosheet stack, patterning the HM layer, and then etching through portions of the nanosheet stack exposed by the patterned HM layer. Such etching may continue through a portion of the substrate 102 as illustrated in FIG. 2.

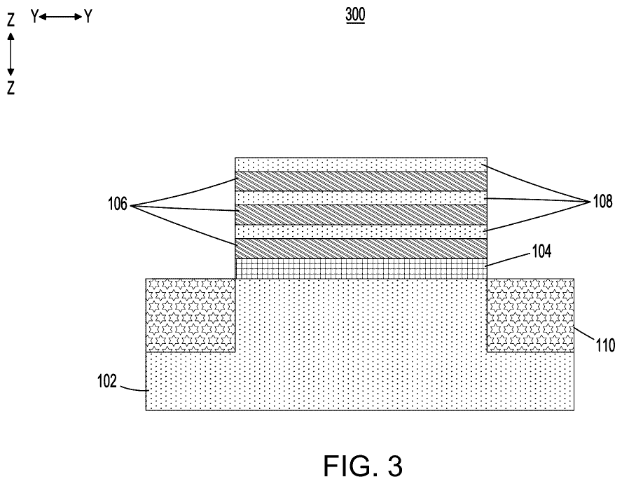

FIG. 3 shows a side cross-sectional view 300 of the FIG. 2 structure following formation of STI regions 110. The STI regions 110 may be formed of a dielectric material such as silicon dioxide (SiO₂), silicon oxycarbide (SiOC), silicon oxynitride (SiON), etc. The STI regions 110 may have a height (in direction Z) in the range of 20 to 100 nm.

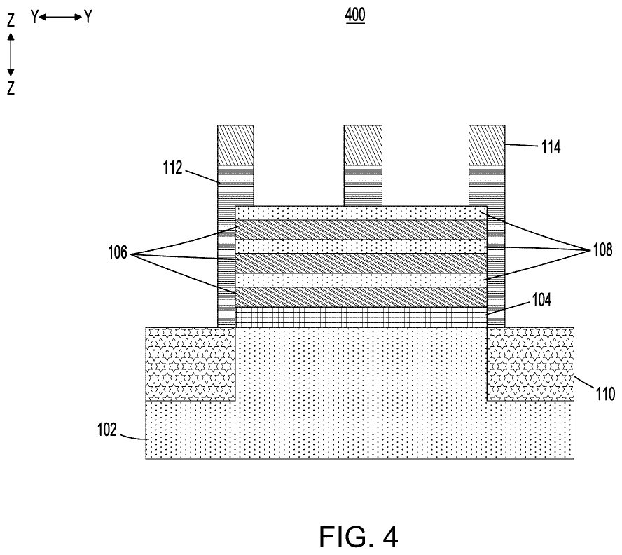

FIG. 4 shows a side cross-sectional view 400 of the FIG. 3 structure following patterning of dummy gate structures. The dummy gate structures include dummy gates 112 and a gate HM layer 114. Material of the dummy gates 112 (e.g., amorphous silicon (a-Si) or amorphous silicon germanium (a-SiGe) over a thin SiO₂ or titanium nitride (TiN) layer, or another suitable material) may be blanket deposited over the structure, followed by formation and patterning of the gate hard mask layer 114 (e.g., formed of silicon nitride (SiN), a multi-layer of SiN and SiO₂, or another suitable material), followed by lithographic processing to result in the patterned dummy gates 112 and gate HM layer 114 as shown in FIG. 4. The dummy gates 112 may each have a width (in direction Y) in the range of 10-100 nm. The gate HM layer 114 may have a height (in direction Z) in the range of 10 nm or larger, and a width (in direction Y) that matches that of the underlying dummy gates 112.

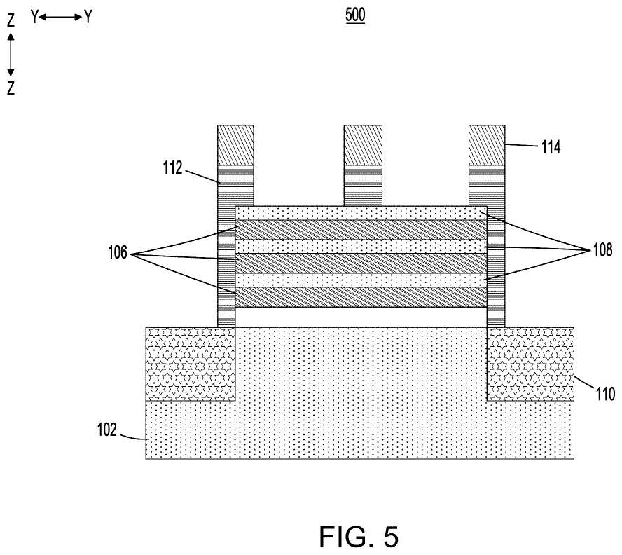

FIG. 5 shows a side cross-sectional view 500 of the FIG. 4 structure following removal of the sacrificial layer 104. The sacrificial layer 104 is removed selective to the sacrificial layers 106.

FIG. 6 shows a side cross-sectional view 600 of the FIG. 5 structure following deposition of a spacer material. The spacer material fills the gap formed by removal of the sacrificial layer 104, to form a bottom dielectric isolation (BDI) layer 116-1. The spacer material is also formed on sidewalls of the dummy gate structures as gate spacers 116-2. The BDI layer 116-1 and gate spacers 116-2 may be formed of any suitable isolation material such as SiN, silicon boron carbide nitride (SiBCN), silicon oxycarbonitride (SiOCN), etc. The isolation material may be blanket deposited, filling the regions exposed by removal of the sacrificial layer 104 to provide the BDI layer 116-1. The portions of the isolation material that overfill the structure may be etched (e.g., using RIE or other suitable etch processing) to result in the gate spacers 116-2.

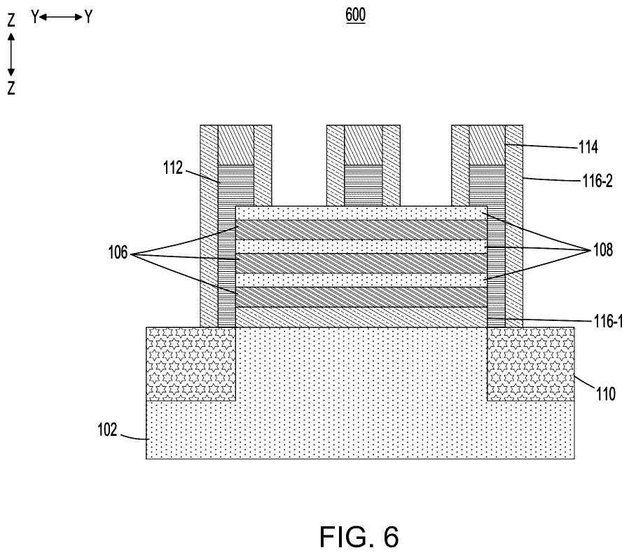

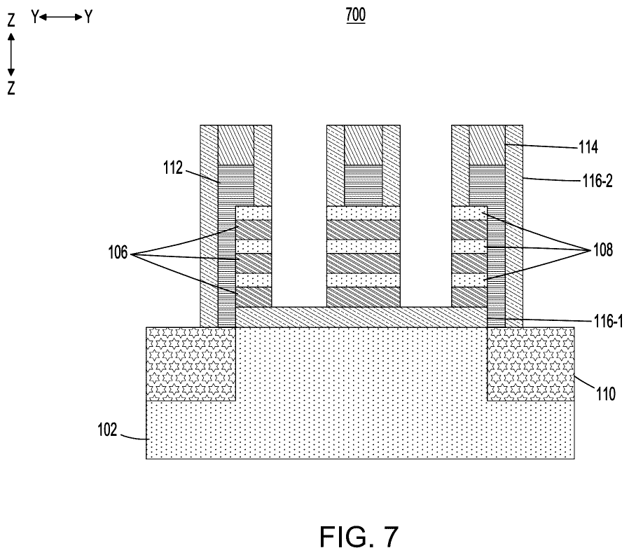

FIG. 7 shows a side cross-sectional view 700 of the FIG. 6 structure following etch-back of exposed portions of the nanosheet stack. Any suitable etch processing, such as reactive-ion etching (RIE), may be used to etch the exposed portions of the nanosheet stack down to the BDI layer 116-1.

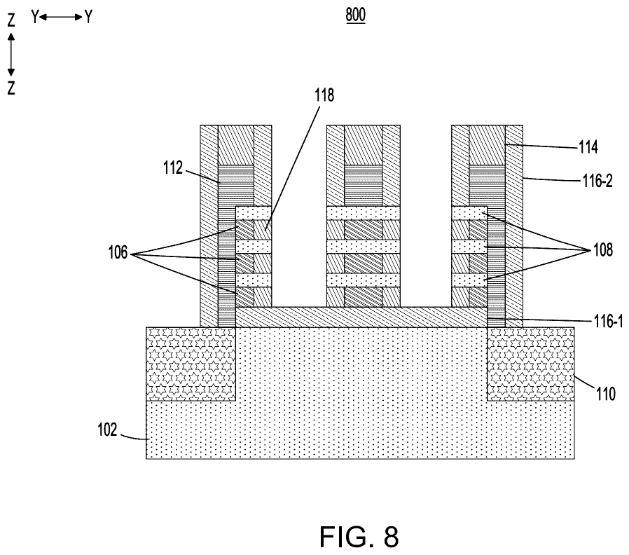

FIG. 8 shows a side cross-sectional view 800 of the FIG. 7 structure following formation of inner spacers 118. The sacrificial layers 106 may be recessed or indented, followed by formation of the inner spacers 118 in the indent regions formed by the recess of the sacrificial layers 106. The inner spacers 118 may be formed to fill indent spaces (e.g., resulting from indent etches of the sacrificial layers 106). The inner spacers 118 may be formed of SiN or another suitable material such as SiBCN, SiCO, SiOCN, etc. The inner spacers 118 may have widths (in direction Y) in the range of 5 to 15 nm, and may have heights (in direction Z) matching that of the sacrificial layers 106.

FIG. 9 shows a side cross-sectional view 900 of the FIG. 8 structure following formation of source/drain epitaxial layers 120-1 and 120-2 (collectively, source/drain epitaxial layers 120). The source/drain epitaxial layers 120 may be formed using an epitaxial growth process. The source/drain epitaxial layers 120 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process used for forming the source/drain epitaxial layers 120 comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, SiGe, Ge, and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³. The source/drain epitaxial layers 120 may have a width (in direction Y) in the range of 10 to 30 nm. The source/drain epitaxial layers 120 may have a height (in direction Z) in the range of 50 to 100 nm such that a top surface of the source/drain epitaxial layers 120 is above the topmost ones of the nanosheet channel layers 108.

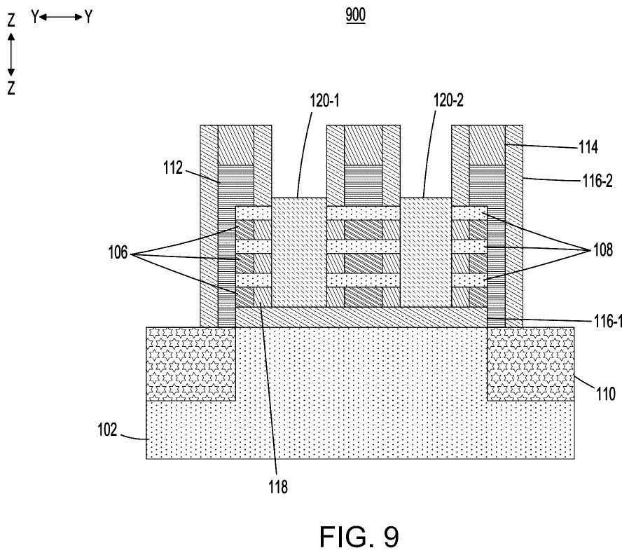

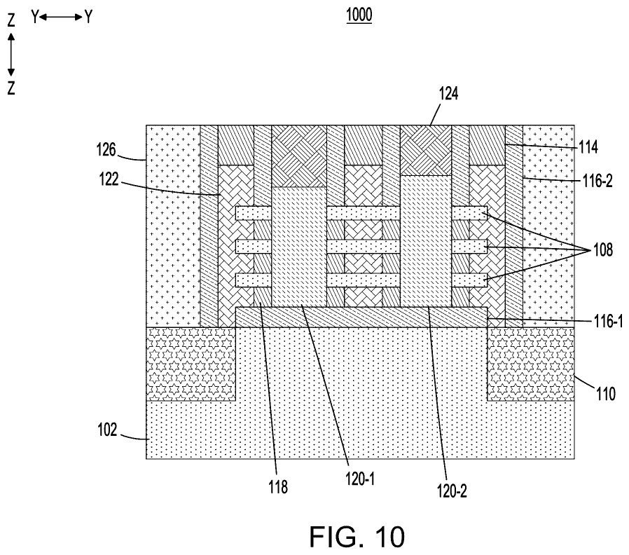

FIG. 10 shows a side cross-sectional view 1000 of the FIG. 9 structure following formation of a gate stack 122, metal trenches 124, and an ILD layer 126. The gate stack 122 may be formed using replacement metal gate (RMG) processing. The RMG processing includes removal of the dummy gates 112 and remaining portions of the sacrificial layers 106 of the nanosheet stack, followed by formation of the gate stack 122.

The gate stack 122 may include a gate dielectric layer and a gate conductor layer. The gate dielectric layer may comprise a high-k dielectric material. Examples of high-k dielectric materials include but are not limited to metal oxides such as hafnium oxide (HfO₂), hafnium silicon oxide (Hf-Si-O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg). The gate dielectric layer may have a uniform thickness in the range of 1 nm to 3 nm.

The gate conductor layer may comprise a metal gate or work function metal (WFM). For nFET devices, the WFM for the gate conductor may be titanium (Ti), aluminum (Al), titanium aluminum (TiAl), titanium aluminum carbon (TiAlC), a combination of Ti and Al alloys, a stack which includes a barrier layer (e.g., of titanium nitride (TiN) or another suitable material) followed by one or more of the aforementioned WFM materials, etc. For pFET devices, the WFM for the gate conductor may be TiN, tantalum nitride (TaN), or another suitable material. In some embodiments, the pFET WFM may include a metal stack, where a thicker barrier layer (e.g., of TiN, TaN, etc.) is formed followed by a WFM such as Ti, Al, TiAl, TiAlC, or any combination of Ti and Al alloys. It should be appreciated that various other materials may be used for gate conductors as desired.

The metal trenches 124 may include a silicide layer such as titanium (Ti), nickel (Ni), nickel platinum (NiPt), etc., a metal adhesion layer (e.g., such as TiN) and a low resistance metal such as tungsten (W), ruthenium (Ru), cobalt (Co) or another suitable material.

The ILD layer 126 may be formed of any suitable isolating material, such as SiO₂, SiOC, SiON, etc. The isolating material may be deposited over the structure, followed by planarization (e.g., using CMP or other suitable processing) to result in the ILD layer 126 as shown in FIG. 10.

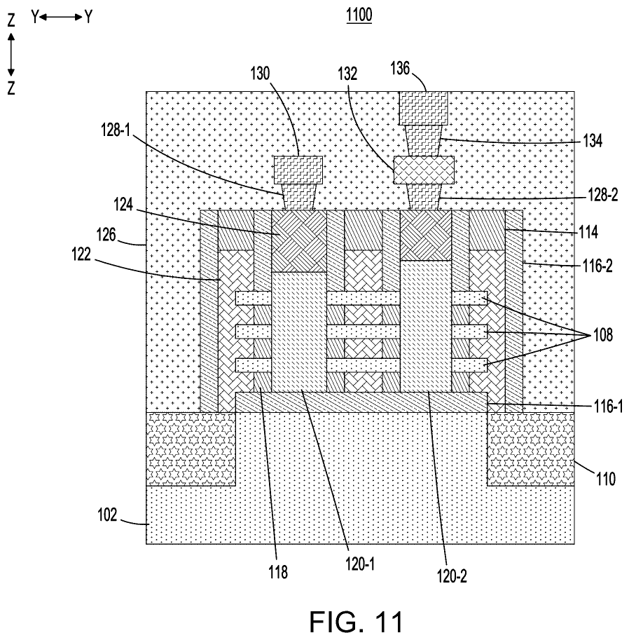

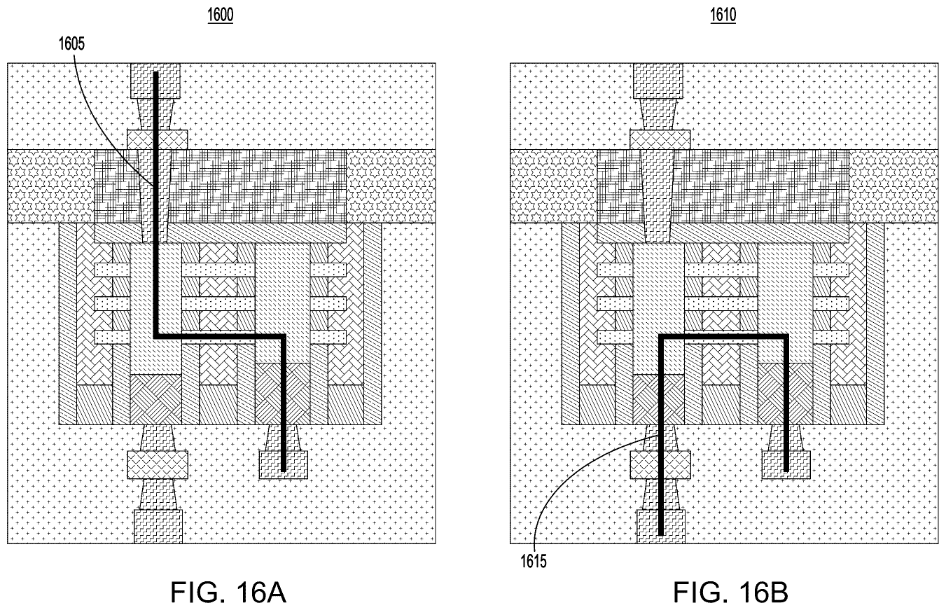

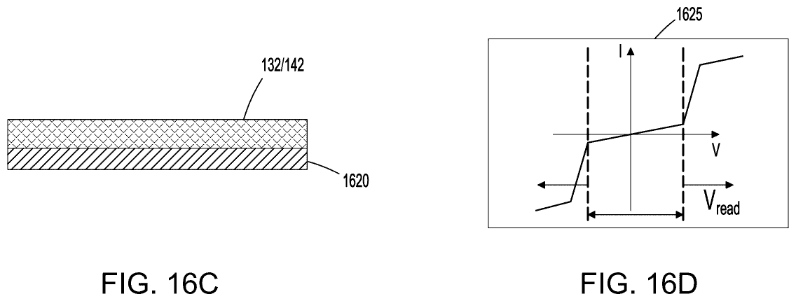

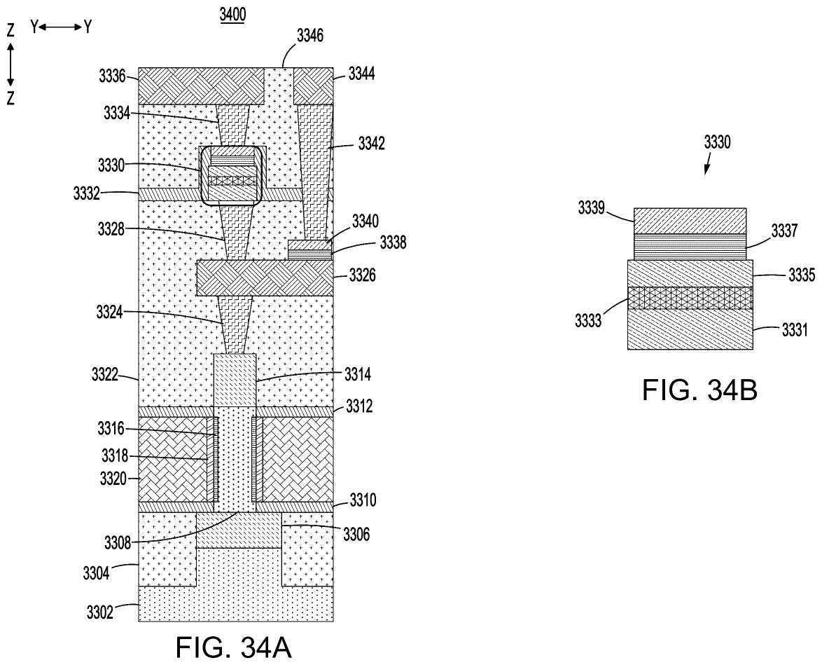

FIG. 11 shows a side cross-sectional view 1100 of the FIG. 10 structure following formation of a BEOL structure including vias 128-1 and 128-2, metallization layer 130, memory cell 132, via 134, and metallization layer 136. Details regarding the structure, composition and sizing of the memory cell 132 (and other memory cells described herein) will be discussed in further detail below with respect to FIGS. 16C, 16D, and 34B.

The vias 128-1 and 128-2 (collectively, vias 128), metallization layer 130, via 134, and metallization layer 136 provide BEOL metallization levels (e.g., formed of copper (Cu) or another suitable material), which are deposited and patterned to form various metallization layers and vias of the BEOL structure. Here the vias 128 provide a first via level (e.g., V1), the metallization layer 130 provides a first metallization level (e.g., M1), the via 134 provides a second via level (e.g., V2), and the metallization layer 136 provides a second metallization layer (e.g., M2). The BEOL structure (e.g., including the vias 128-1 and 128-2, the metallization layer 130, the memory cell 132, the via 134, and the metallization layer 136) are embedded within ILD layer 126. The vias 128 and 134 may have a width (in direction Y) in the range of 10 to 50 nm and a height (in direction Z) in the range of 10 to 100 nm. The metallization layers 130 and 136 may have a width (in direction Y) in the range of 10 to 50 nm and a height (in direction Z) in the range of 10 to 100 nm.

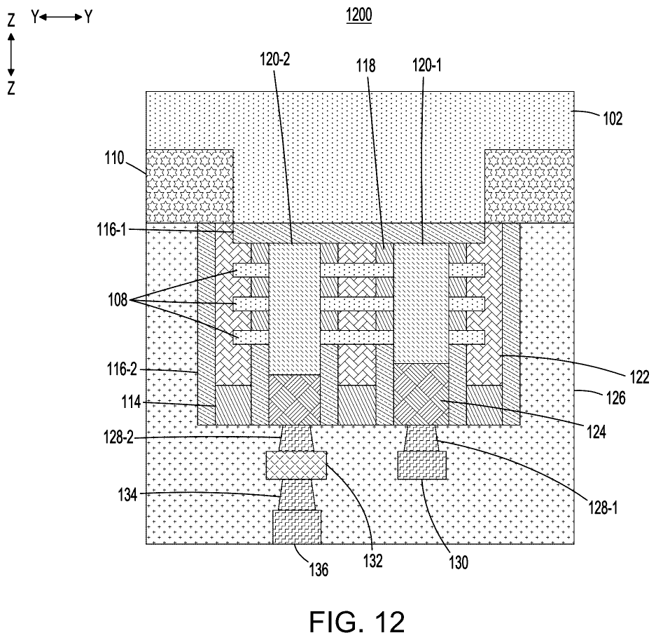

FIG. 12 shows a side cross-sectional view 1200 of the FIG. 11 structure following a wafer flip.

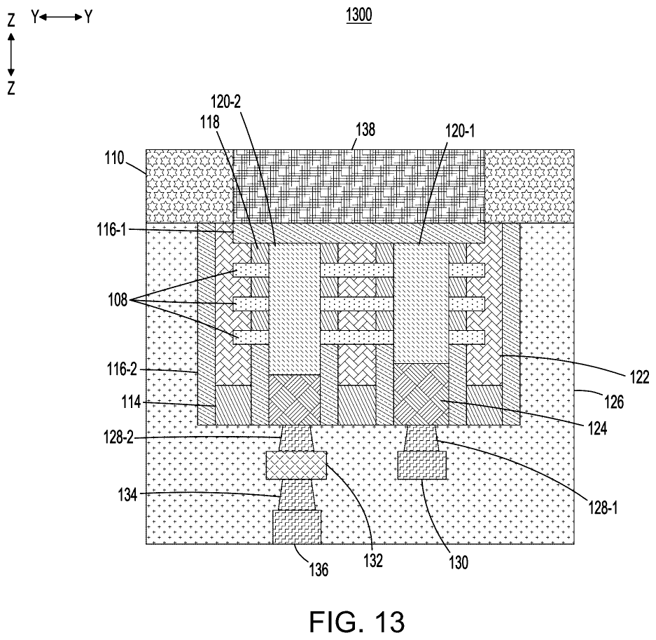

FIG. 13 shows a side cross-sectional view 1300 of the FIG. 12 structure following removal of the substrate 102 and formation of an ILD layer 138. The ILD layer 138 may be formed of materials similar to that of the ILD layer 126. The substrate 102 may be removed using any suitable etch processing. Material of the ILD layer 138 may then be deposited over the structure and then planarized (e.g., using CMP or other suitable processing).

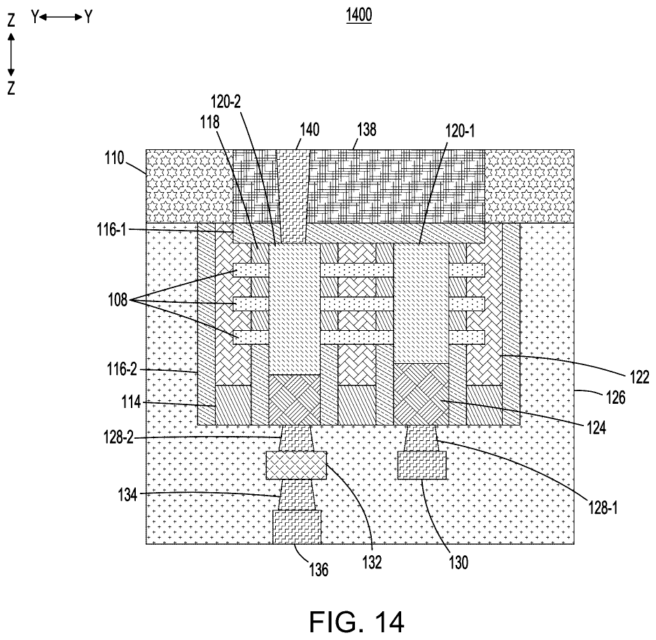

FIG. 14 shows a side cross-sectional view 1400 of the FIG. 13 structure following contact formation of a via 140 in the ILD layer 138. A mask layer may be patterned over the structure, followed by etching through the ILD layer 138 and the BDI layer 116-1. The via 140 is then formed to contact the source/drain epitaxial layer 120-2.

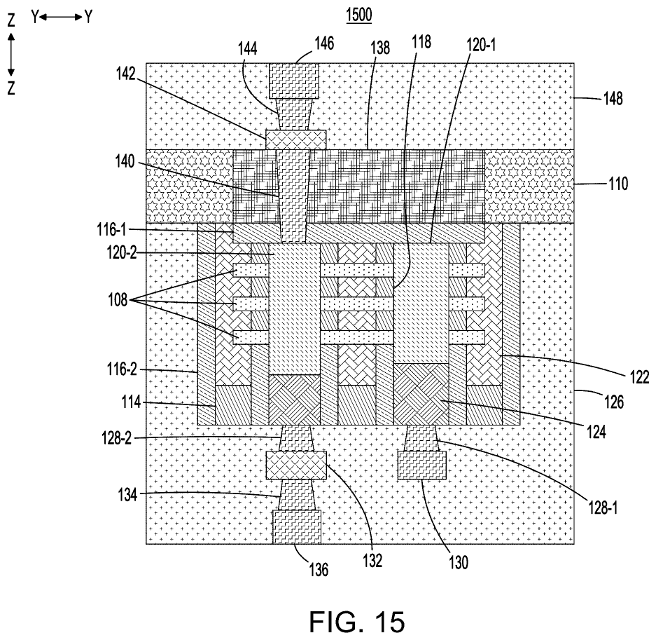

FIG. 15 shows a side cross-sectional view 1500 of the FIG. 14 structure following formation of another BEOL structure including another memory cell 142, via 144 and metallization layer 146 in an ILD layer 148. The ILD layer 148 may be formed of similar materials as the ILD layer 126. The memory cell 142, via 144 and metallization layer 146 may be formed of similar materials and with similar sizing and processing as that described above with respect to the memory cell 132, the vias 128-1, 128-2 and 134, and the metallization layers 130 and 136. The via 144 may provide a third via level (e.g., V3) and the metallization layer 146 may provide a third metallization level (e.g., M3).

FIG. 16A shows a side cross-sectional view 1600 of the FIG. 15 structure illustrating a current path 1605 for the memory cell 142, and FIG. 16B shows a side cross-sectional view 1610 of the FIG. 15 structure illustrating a current path 1615 for the memory cell 132. The current path 1605 is from the metallization layer 130 to the via 128-1, one of the metal trenches 124, through a portion of the source/drain epitaxial layer 120-1, across the “bottom” nanosheet channel layer 108, “up” through the source/drain epitaxial layer 120-2 and through the via 140, the memory cell 142, the via 144 and the metallization layer 146. The current path 1615 is from the metallization layer 130 to the via 128-1, one of the metal trenches 124, through a portion of the source/drain epitaxial layer 120-1, across the “bottom” nanosheet channel layer 108, “down” through the source/drain epitaxial layer 120-2 and through the other one of the metal trenches 124, the via 128-2, the memory cell 132, the via 134 and the metallization layer 136.

FIG. 16C shows a detailed view of the memory cells 132/142, where the memory cells 132/142 include a selector device 1620 which provides threshold switching in the memory cells 132/142. The selector device 1620 advantageously provides a bipolar diode which prevents leakage current during sensing of the memory cells 132/142. FIG. 16D shows a plot 1625 illustrating resistance of the selector device 1620 as a function of current (I) and voltage (V).

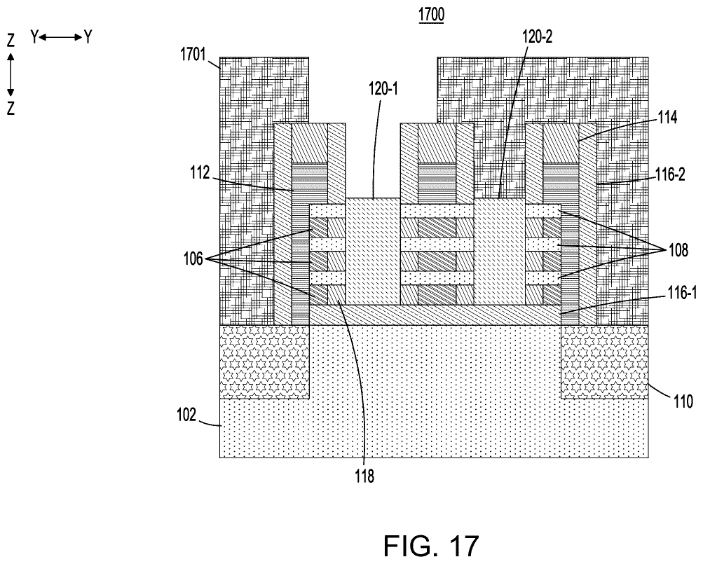

FIG. 17 shows a side cross-sectional view 1700 of the FIG. 9 structure, following patterning of an organic planarization layer (OPL) 1701 over the structure to expose the source/drain epitaxial layer 120-1.

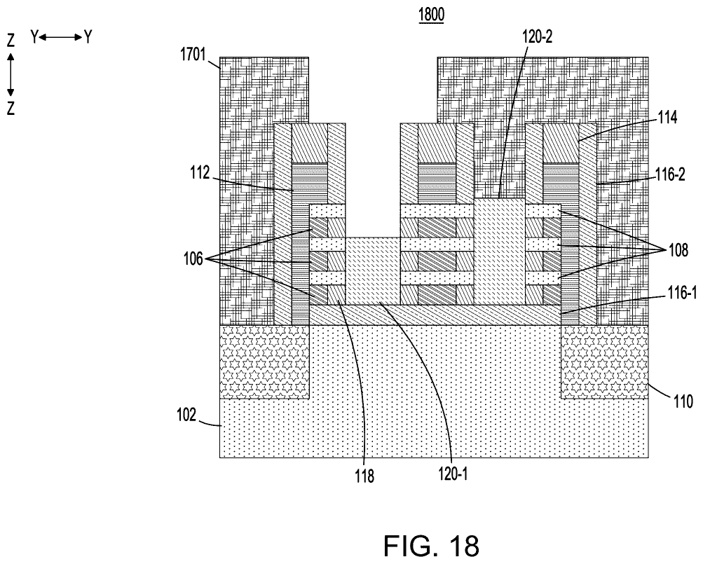

FIG. 18 shows a side cross-sectional view 1800 of the FIG. 17 structure following recess of the source/drain epitaxial layer 120-1. The source/drain epitaxial layer 120-1 is recessed below a topmost one of the nanosheet channel layers 108. The source/drain epitaxial layer 120-1 may be recessed using any suitable etch processing, such as RIE.

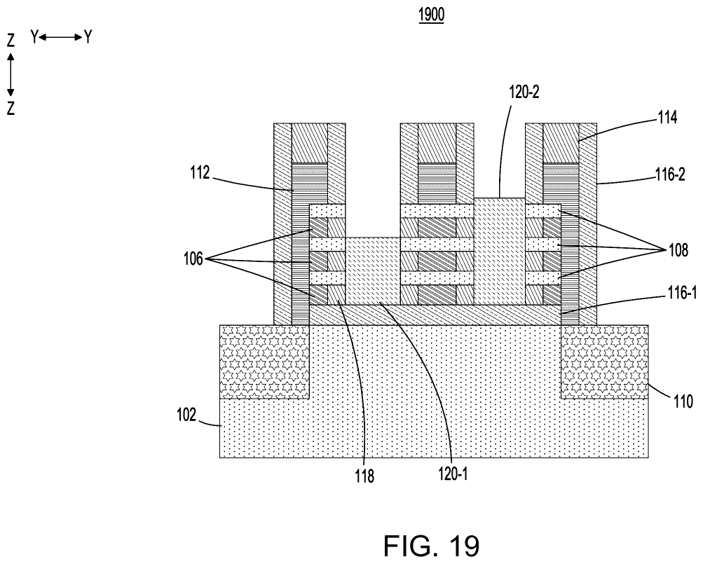

FIG. 19 shows a side cross-sectional view 1900 of the FIG. 18 structure following removal of the OPL 1701.

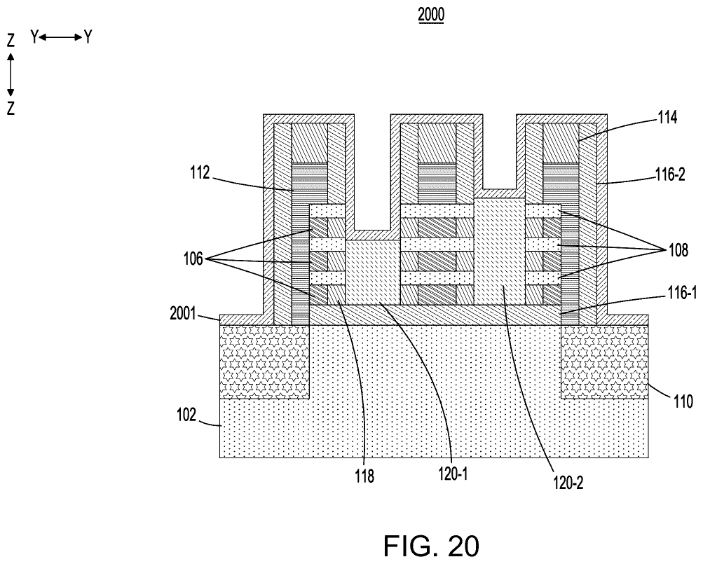

FIG. 20 shows a side cross-sectional view 2000 of the FIG. 19 structure following formation of a liner 2001. The liner 2001 may be formed of SiN or another suitable material such as SiBCN, SiOCN, a high-k dielectric, etc. The liner 2001 may have a uniform thickness in the range of 3 to 20 nm. The liner 2001 may be formed using any suitable deposition process.

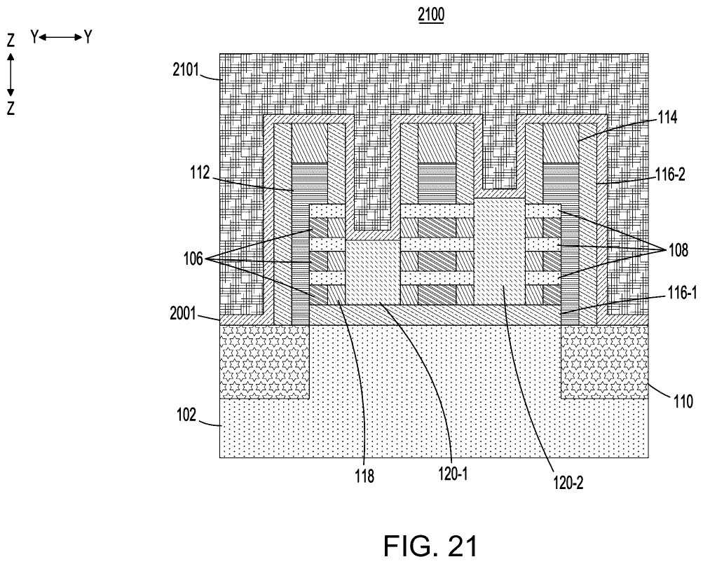

FIG. 21 shows a side cross-sectional view 2100 of the FIG. 20 structure following formation of an OPL 2101. The OPL 2101 may be blanket coated to overfill the structure.

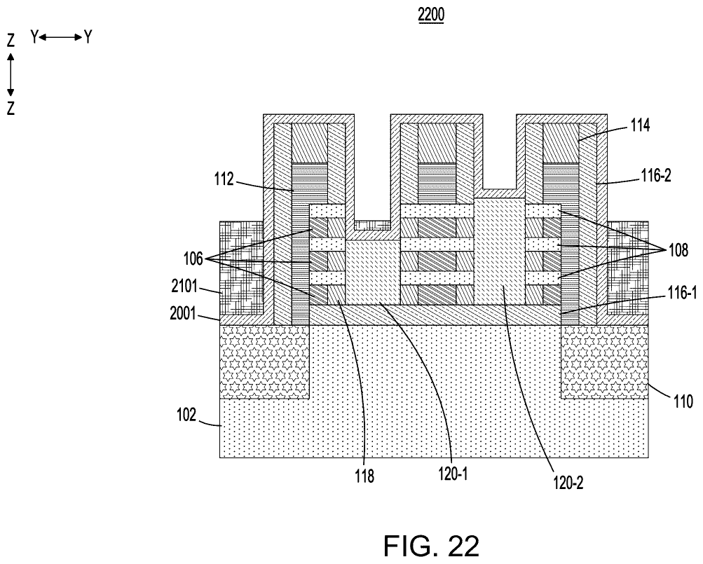

FIG. 22 shows a side cross-sectional view 2200 of the FIG. 21 structure following recess of the OPL 2101. The OPL 2101 may be recessed using any suitable etch processing. The OPL 2101 is recessed below the topmost one of the nanosheet channel layers 108.

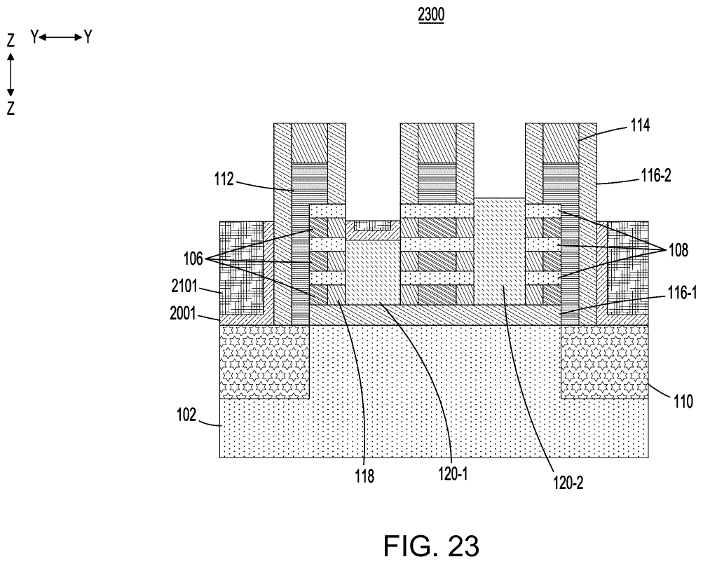

FIG. 23 shows a side cross-sectional view 2300 of the FIG. 22 structure following removal of portions of the liner 2001 exposed by the OPL 2101. The portions of the liner 2001 may be removed using any suitable etch processing.

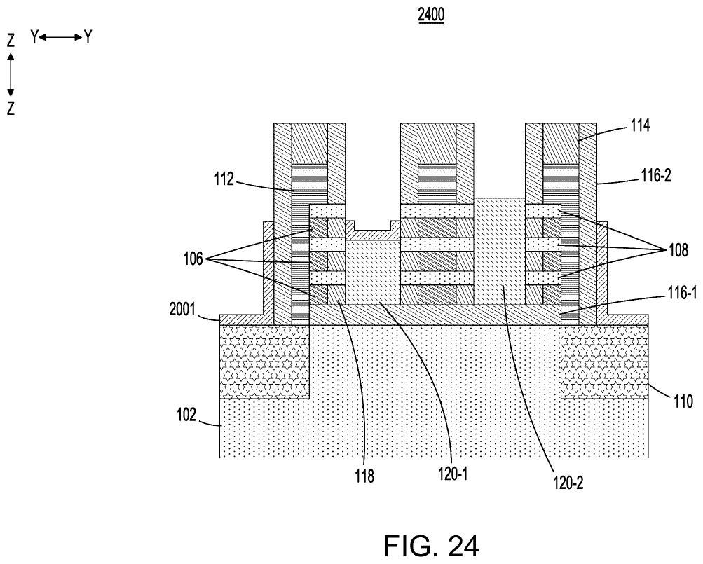

FIG. 24 shows a side cross-sectional view 2400 of the FIG. 23 structure following removal of the remaining portions of the OPL 2101.

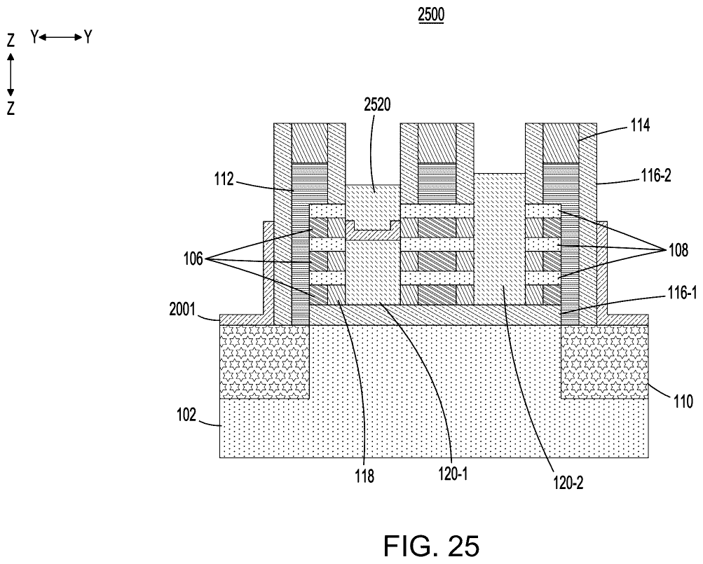

FIG. 25 shows a side cross-sectional view 2500 of the FIG. 24 structure following formation of a source/drain epitaxial layer 2520 over the liner 2001 that is formed over the source/drain epitaxial layer 120-1. The epitaxial growth process used to form the source/drain epitaxial layer 2520 also results in formation of additional material for the source/drain epitaxial layer 120-2 as illustrated.

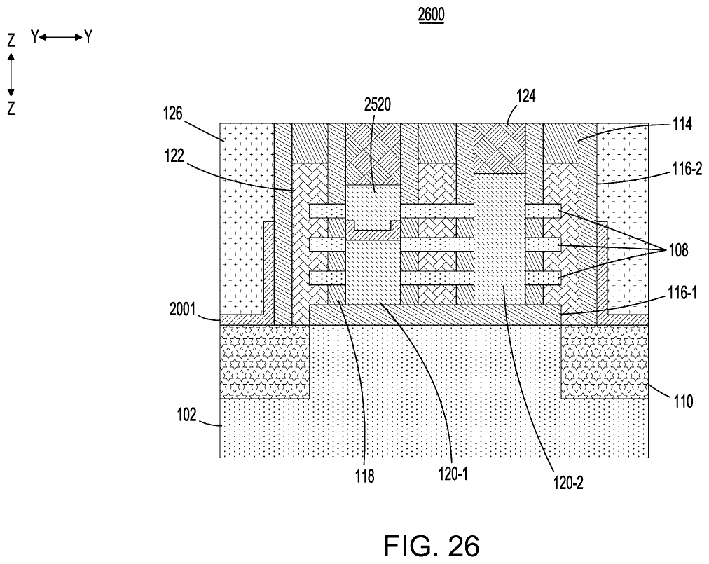

FIG. 26 shows a side cross-sectional view 2600 of the FIG. 25 structure following formation of the gate stack 122, metal trenches 124 and ILD layer 126 using processing similar to that described above with respect to FIG. 10.

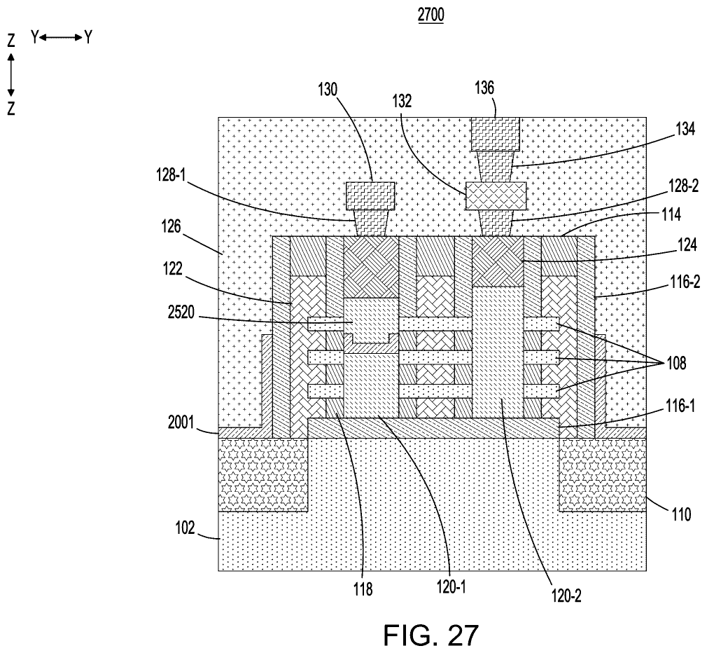

FIG. 27 shows a side cross-sectional view 2700 of the FIG. 26 structure following formation of the BEOL structure including the vias 128-1 and 128-2, the metallization layer 130, the memory cell 132, the via 134, and the metallization layer 136 using processing similar to that described above with respect to FIG. 11.

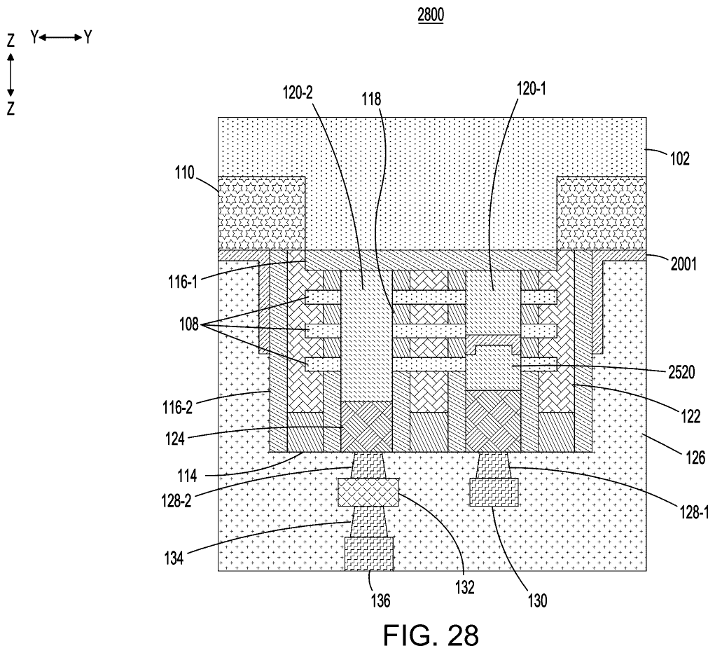

FIG. 28 shows a side cross-sectional view 2800 of the FIG. 27 structure following a wafer flip similar to that of FIG. 12.

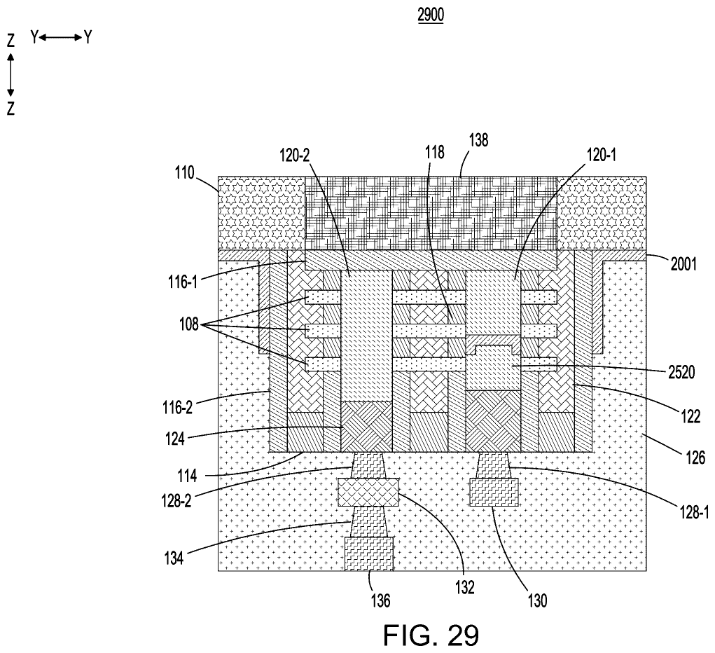

FIG. 29 shows a side cross-sectional view 2900 of the FIG. 28 structure following removal of the substrate 102 and formation of the ILD layer 138 using processing similar to that described above with respect to FIG. 13.

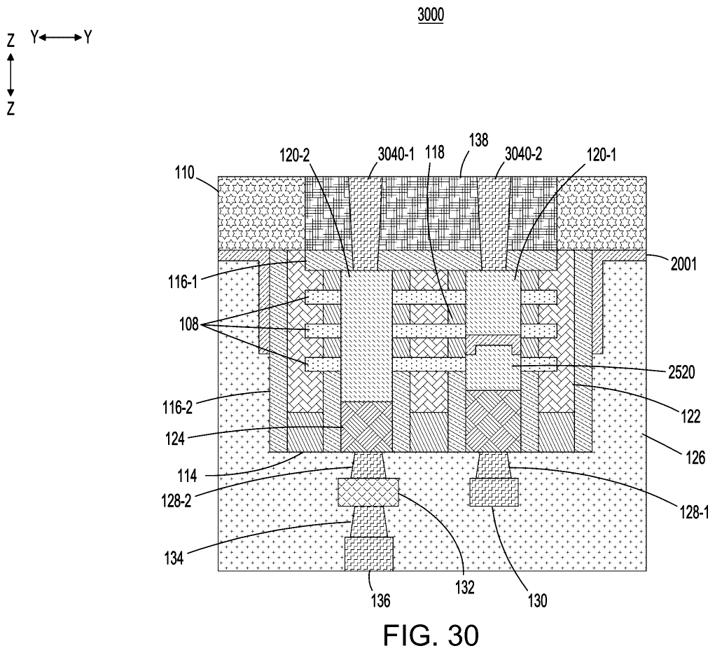

FIG. 30 shows a side cross-sectional view 3000 of the FIG. 29 structure following contact formation of vias 3040-1 and 3040-2 (collectively, vias 3040) to the source/drain epitaxial layers 120-2 and 120-1, respectively, using processing similar to that described above with respect to FIG. 14 and the formation of the via 140.

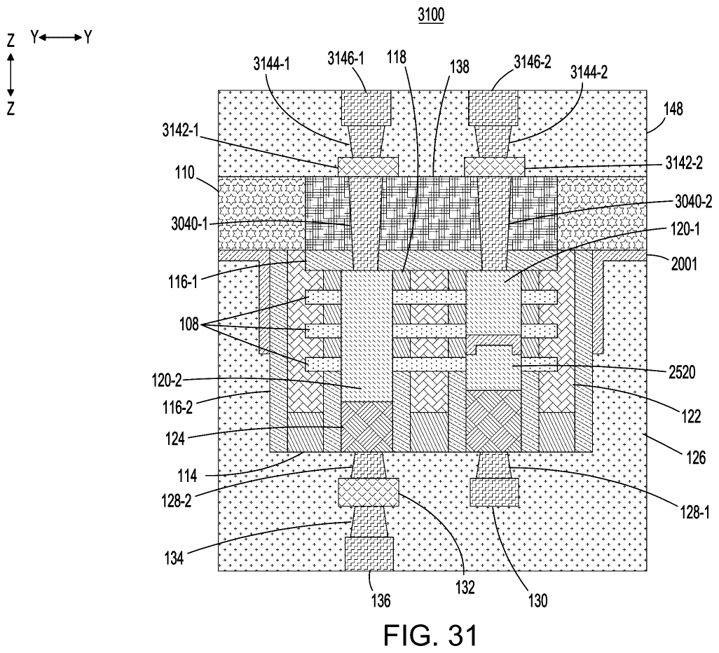

FIG. 31 shows a side cross-sectional view 3100 of the FIG. 30 structure following formation of another BEOL structure including memory cells 3142-1 and 3142-2 (collectively, memory cells 3142), vias 3144-1 and 3144-2 (collectively, vias 3144) and metallization layers 3146-1 and 3146-2 (collectively, metallization layers 3146) using processing similar to that described above with respect to FIG. 15 and the formation of the memory cell 142, the via 144 and the metallization layer 146. The vias 3144 provide a third via level (e.g., V3) and the metallization layers 3146 provide a third metallization level (e.g., M3).

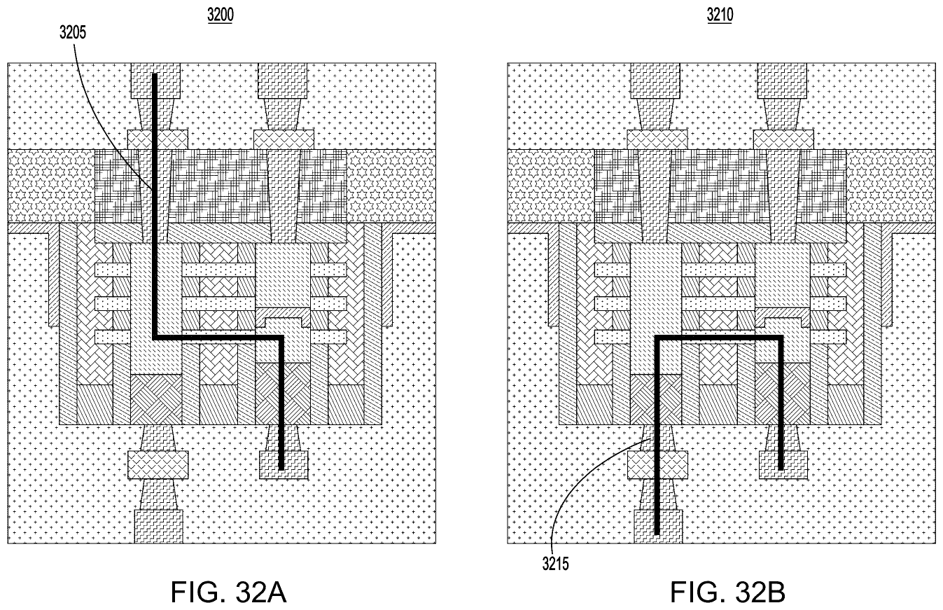

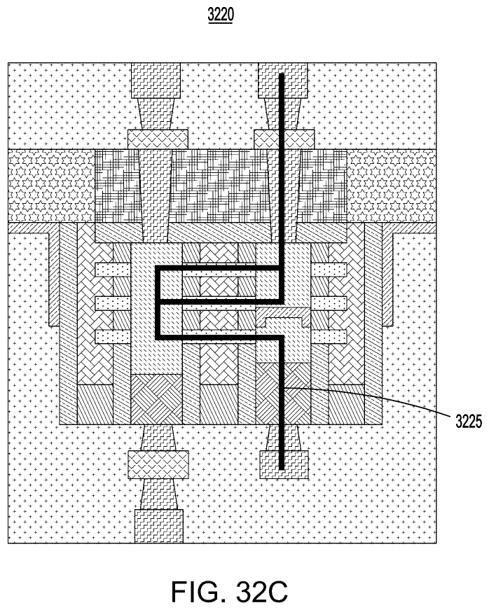

FIG. 32A shows a side cross-sectional view 3200 of the FIG. 31 structure illustrating a current path 3205 for the memory cell 3142-1, FIG. 32B shows a side cross-sectional view 3210 of the FIG. 31 structure illustrating a current path 3215 for the memory cell 132, and FIG. 32C shows a side cross-sectional view 3220 of the FIG. 31 structure illustrating a current path 3225 for the memory cell 3142-2. The current path 3205 is from the metallization layer 130 to the via 128-1, through one of the metal trenches 124, through a portion of the source/drain epitaxial layer 2520, across the “bottom” nanosheet channel layer 108, “up” through the source/drain epitaxial layer 120-2 and through the via 3040-1, the memory cell 3142-1, the via 3144-1 and the metallization layer 3146-1. The current path 3215 is from the metallization layer 130 to the via 128-1, through one of the metal trenches 124, through a portion of the source/drain epitaxial layer 2520, across the “bottom” nanosheet channel layer 108, “down” through the source/drain epitaxial layer 120-2 and through the other one of the metal trenches 124, the via 128-2, the memory cell 132, the via 134 and the metallization layer 136. The current path 3225 is from the metallization layer 130 to the via 128-1, through one of the metal trenches 124, through a portion of the source/drain epitaxial layer 2520, across the “bottom” nanosheet channel layer 108, “up” through the source/drain epitaxial layer 120-2, across the two uppermost nanosheet channel layers 108, “up” through the source/drain epitaxial layer 120-1, and through the via 3040-2, the memory cell 3142-2, the via 3144-3 and the metallization layer 3146-2. The memory cells 3142 may include selector devices such as selector device 1620 in a manner similar to that of the memory cells 132/142.

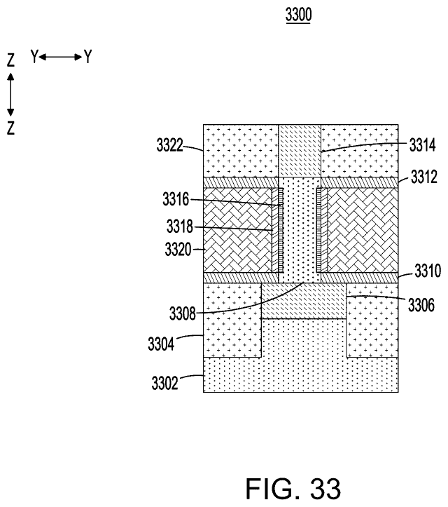

FIG. 33 shows a side cross-sectional view 3300 of a vertical transistor structure, including a substrate 3302, ILD layer 3304, a first (e.g., bottom) epitaxial layer 3306, a vertical channel layer 3308, a first (e.g., bottom) spacer 3310, a second (e.g., top) spacer 3312, a second (e.g., top) epitaxial layer 3314, a gate stack including a gate dielectric layer 3316, a gate WFM layer 3318 and a gate conductor 3320, and an ILD layer 3322. The substrate 3302 may be formed of similar materials as the substrate 102. The ILD layers 3304 and 3322 may be formed of similar materials as the ILD layer 126. The first epitaxial layer 3306 and the second epitaxial layer 3314 may be formed using similar processing and materials as the source/drain epitaxial layers 120. The vertical channel layer 3308 may be formed of similar materials as the nanosheet channel layers 108. The first spacer 3310 and the second spacer 3312 may be formed of similar materials as the BDI layer 116-1 and the gate spacers 116-2. The gate dielectric layer 3316, the gate WFM layer 3318 and the gate conductor 3320 may be formed of similar materials as the gate stack 122.

In the vertical transistor structure of FIG. 33, the first epitaxial layer 3306 may have a width (in direction Y) in the range of 10 to 50 nm and a height (in direction Z) in the range of 10 to 100 nm, the vertical channel layer 3308 have a width (in direction Y) in the range of 10 to 50 nm and a height (in direction Z) in the range of 10 to 100 nm, the second epitaxial layer 3314 may have a width (in direction Y) in the range of 10 to 50 nm and a height (in direction Z) in the range of 10 to 100 nm, the first spacer 3310 and second spacer 3312 may each have a height (in direction Z) in the range of 3 to 20 nm. The gate dielectric layer 3316 may have a thickness in the range of 1 nm to 3 nm, and the gate WFM layer 3318 may have a thickness in the range of 3 to 20 nm.

FIG. 34A shows a side cross-sectional view 3400 of the FIG. 33 structure following formation of a BEOL structure including a via 3324, metal layer 3326, via 3328, memory structure 3330, insulator layer 3332, via 3334, metal layer 3336, selector device 3338, electrode 3340, via 3342, metal layer 3344 and ILD layer 3346. The via 3324 connects the second epitaxial layer 3314 to the metal layer 3326. The via 3328 connects the metal layer 3326 and the memory structure 3330. The via 3334 connects the memory structure 3330 to the metal layer 3336. The selector device 3338 is connected to the electrode 3340 as well as the metal layer 3326, and the electrode 3340 is connected to the via 3342 and the metal layer 3344. The vias 3324, 3328, 3334 and 3342 have respective widths (in direction Y) in the range of 10 to 50 nm and heights which vary in order to provide the interconnection illustrated in FIG. 34A. The vias 3324, 3328, 3334 and 3342 may be formed of Cu or another suitable material. The metal layers 3326, 3336 and 3344 may be formed of materials similar to that of the metal trenches 124, and may have heights (in direction Z) in the range of 5 to 20 nm. The insulator layer 3332 may be formed of similar materials and with similar sizing as the first spacer 3310 and the second spacer 3312. The ILD layer 3346 may be formed of similar materials as the ILD layer 3322.

The selector device 3338 may be formed of an ovonic threshold switching (OTS) selector material such as a germanium-selenium (Ge-Se) alloy. The selector device 3338 may have a height (in direction Z) in the range of 5 to 30 nm, and may have a width (in direction Y) in the range of 10 to 50 nm. The electrode 3340 may be formed of W, TiN, Co, platinum (Pt), TaN, tantalum (Ta), titanium (Ti) or another suitable material, may have a height (in direction Z) in the range of 10 to 50 nm, and a width (in direction Y) in the range of 10 to 50 nm which matches that of the selector device 3338. The selector device 3338 and the electrode 3340 provide a bipolar diode that prevents leakage current during sensing. The plot 1625 of FIG. 16D illustrates the resistance of the selector device 3338 as a function of current (I) and voltage (V).

FIG. 34B shows a detailed view of the memory structure 3330, which includes a first (e.g., bottom) electrode 3331, a memory switching layer 3333, a second (e.g., middle) electrode 3335, a selector device 3337, and a third (e.g., top) electrode 3339. The first electrode 3331 and the second electrode 3335 may each be formed of W, TiN, Co, Pt, Tan, Ta, Ti or another suitable material, may have heights (in direction Z) in the range of 10 to 50 nm, and may have widths (in direction Y) in the range of 10 to 50 nm. The material of the memory switching layer 3333 may vary depending on the type of memory device used (e.g., an oxide for RRAM, a magnetic tunnel junction (MTJ) stack for MRAM or STTRAM, a ferroelectric material for FeRAM, a phase-change material for PCRAM, etc.). The selector device 3337 and the third electrode 3339 provide a bipolar diode that prevents leakage current during sensing. The plot 1625 of FIG. 16D illustrates the resistance of the selector device 3337 as a function of current (I) and voltage (V). The selector device 3337 and the third electrode 3339 may be formed of similar materials and with similar sizing as that described above with respect to the selector device 3338 and the electrode 3340.

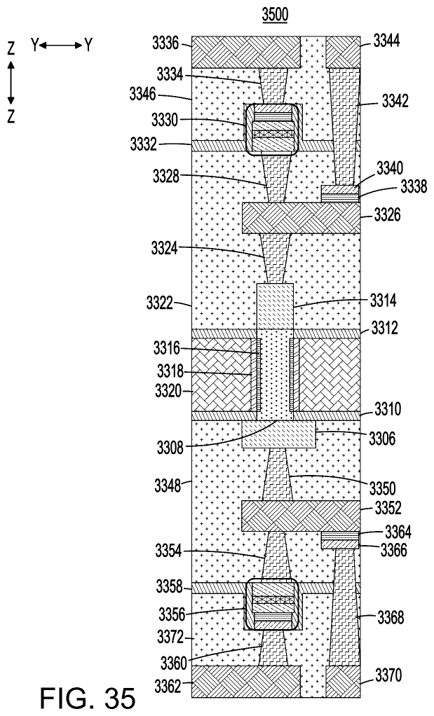

FIG. 35 shows a side cross-sectional view 3500 of the structure of FIG. 34A following formation of another BEOL structure including ILD layer 3348, via 3350, metal layer 3352, via 3354, memory structure 3356, insulator layer 3358, via 3360, metal layer 3362, selector device 3364, electrode 3366, via 3368, metal layer 3370 and ILD layer 3372. The ILD layer 3348, via 3350, metal layer 3352, via 3354, memory structure 3356, insulator layer 3358, via 3360, metal layer 3362, selector device 3364, electrode 3366, via 3368, metal layer 3370 and ILD layer 3372 may be formed of similar materials and with similar processing and sizing as that described above with respect to the ILD layer 3322, via 3324, metal layer 3326, via 3328, memory structure 3330, insulator layer 3332, via 3334, metal layer 3336, selector device 3338, electrode 3340, via 3342, metal layer 3344 and ILD layer 3346, respectively.

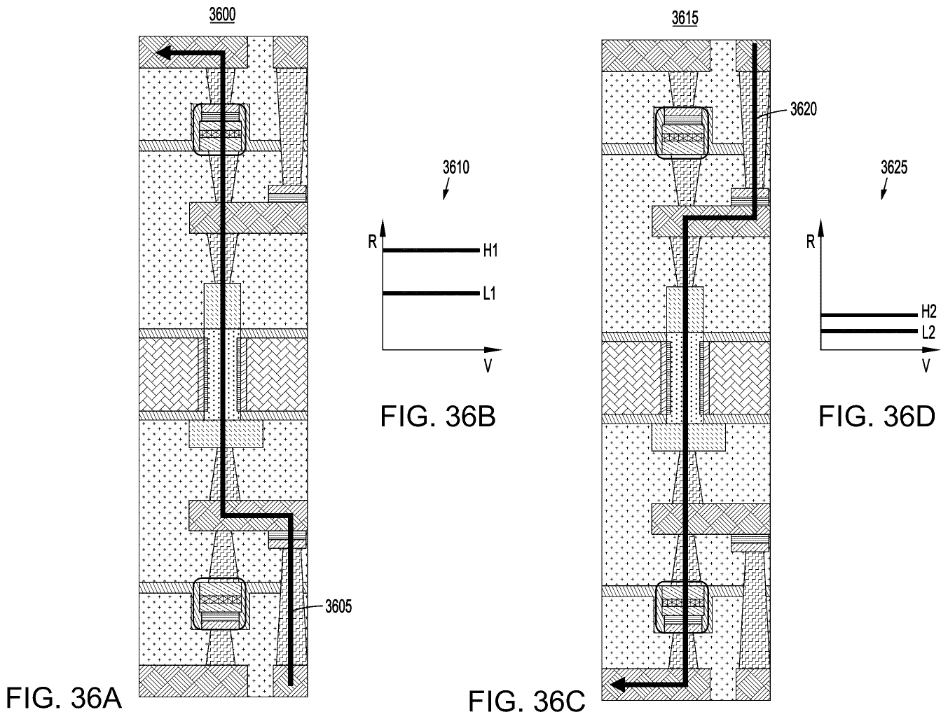

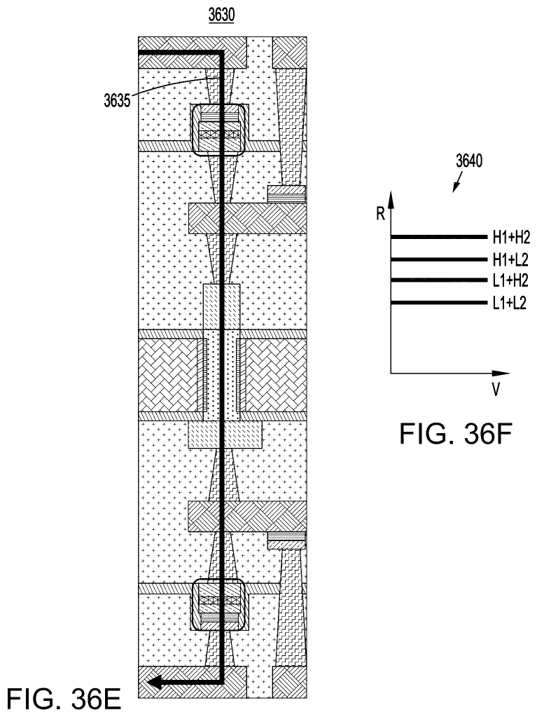

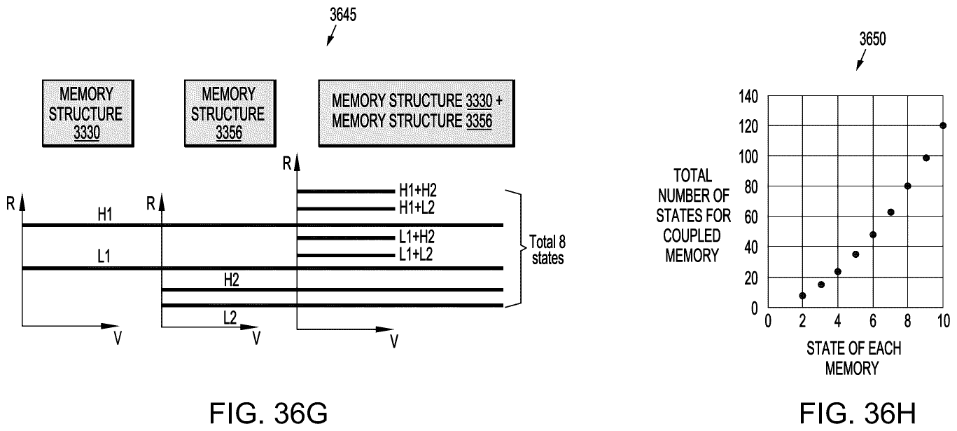

FIG. 36A shows a side cross-sectional view 3600 of the FIG. 35 structure illustrating a current path 3605 for programming and sensing of the memory structure 3330, and FIG. 36B shows a plot 3610 of resistance (R) and voltage (V) showing resistance values H1, L1 for the memory structure 3330. Here, there is a two-level resistance for programming and sensing of the memory structure 3330. The current path 3605 is from the metal layer 3370 to the via 3368, electrode 3366, selector device 3364, metal layer 3352, via 3350, first epitaxial layer 3306, vertical channel layer 3308, second epitaxial layer 3314, via 3324, metal layer 3326, via 3328, memory structure 3330, via 3334 and metal layer 3336.

FIG. 36C shows a side cross-sectional view 3615 of the FIG. 35 structure illustrating a current path 3620 for programming and sensing of the memory structure 3356, and FIG. 36D shows a plot 3625 of resistance (R) and voltage (V) showing resistance values H2, L2 for the memory structure 3356. Here, there is a two-level resistance for programming and sensing of the memory structure 3356. The current path 3620 is from the metal layer 3344 to the via 3342, electrode 3340, selector device 3338, metal layer 3326, via 3324, second epitaxial layer 3314, vertical channel layer 3308, first epitaxial layer 3306, via 3350, metal layer 3352, via 3354, memory structure 3356, via 3360 and metal layer 3362.

FIG. 36E shows a side cross-sectional view 3630 of the FIG. 35 structure illustrating a current path 3635 for programming and sensing of a combination of the memory structures 3330 and 3356, and FIG. 36F shows a plot 3640 of resistance (R) and voltage (V) showing resistance values H1+H2, H1+L2, L1+H2 and L1+L2 for the combination of the memory structures 3330 and 3356. Here, there is a four-level resistance for programming and sensing of the combination of the memory structures 3330 and 3356. The current path 3635 is from the metal layer 3336 to the via 3334, memory structure 3330, via 3328, metal layer 3326, via 3324, second epitaxial layer 3314, vertical channel layer 3308, first epitaxial layer 3306, via 3350, metal layer 3352, via 3354, memory structure 3356, via 3360 and metal layer 3362.

FIG. 36G shows a plot 3645 of the different resistance values H1, L1, H2, L2, H1+H2, H1+L2, L1+H2 and L1+L2 which may be sensed (e.g., by applying a voltage and measuring the current in the different current paths 3605, 3620 and 3635) to determine a state of the multi-level memory cell formed by the combination of the memory structures 3330 and 3356. FIG. 36H shows a plot 3650 illustrating the total number of states for the coupled memory structures 3330 and 3356 and the state of each memory. Generally, for a memory structure having n states (e.g., where n>1), a memory cell combining two of such memory structures has a total number n²+2n states. Here, where each of the memory structures 3330 and 3356 has two states (e.g., n=2), the memory cell formed by the combination of the memory structures 3330 and 3356 has a total of 8 states.

FIG. 36I shows a side cross-sectional view 3655 of the FIG. 35 structure illustrating a current path 3660 for logic operation only. Here, the current path 3660 is from metal layer 3344 to the via 3342, the electrode 3340, the selector device 3338, the metal layer 3326, the via 3324, the second epitaxial layer 3314, the vertical channel layer 3308, the first epitaxial layer 3306, the via 3350, the metal layer 3352, the selector device 3364, the electrode 3366, the via 3368 and the metal layer 3370.

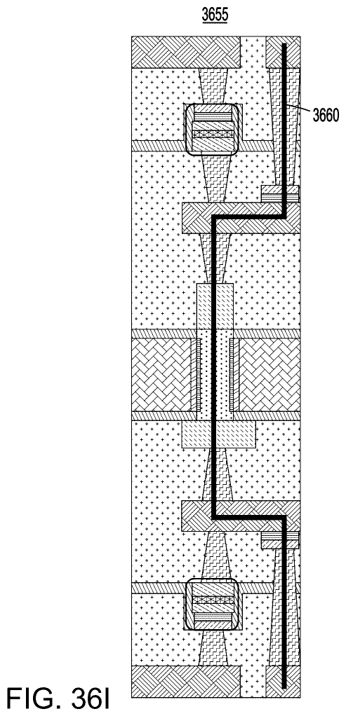

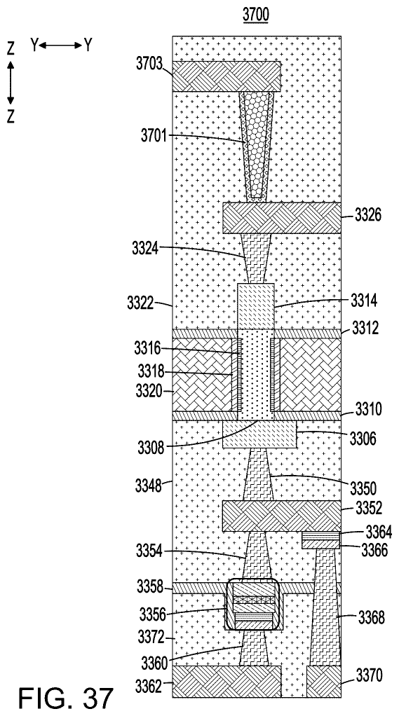

FIG. 37 shows a side cross-sectional view 3700 of a structure which includes the vertical transistor and the “bottom” memory cell of the FIG. 35 structure, but where the “top” memory cell of the FIG. 35 structure is replaced with a capacitor structure. The structure of FIG. 37 thus includes the first epitaxial layer 3306, vertical channel layer 3308, first spacer 3310, second spacer 3312, second epitaxial layer 3314, gate dielectric layer 3316, gate WFM layer 3318, gate conductor 3320, ILD layer 3322, via 3324, metal layer 3326, ILD layer 3348, via 3350, metal layer 3352, via 3354, memory structure 3356, insulator layer 3358, via 3360, metal layer 3362, selector device 3364, electrode 3366, via 3368, metal layer 3370 and ILD layer 3372. In addition, the FIG. 37 structure includes a capacitor 3701 which connects to the metal layer 3326 at one end and a metal layer 3703 at the other end. The metal layer 3703 may be formed of similar materials and with similar sizing as the metal layer 3336. The capacitor 3701 may include an electrode (e.g., formed of TiN, W, TaN or another suitable material) and a dielectric material (e.g., HfO₂, Al₂O₃, ZrO₂ or another suitable material). The capacitor 3701 may have a width (in direction Y) in the range of 10 to 50 nm and a height (in direction Z) in the range of 100 to 3000 nm.

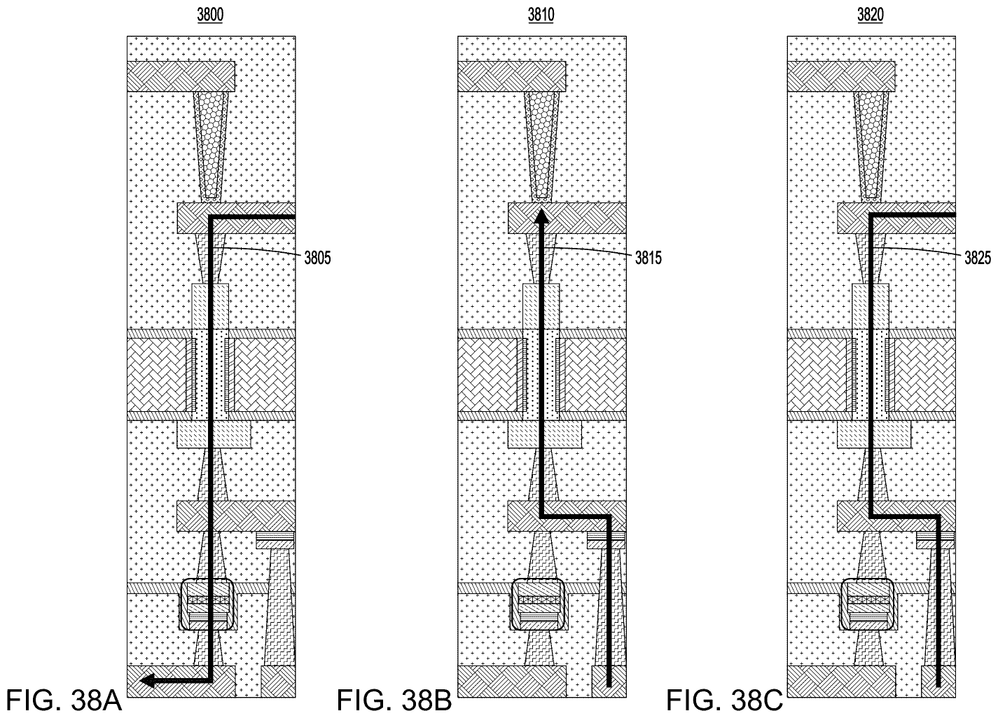

FIG. 38A shows a side cross-sectional view 3800 of the FIG. 37 structure illustrating a current path 3805 for programming and sensing of the memory structure 3356. The current path 3805 is from the metal layer 3326 to the via 3324, the second epitaxial layer 3314, the vertical channel layer 3308, the first epitaxial layer 3306, the via 3350, the metal layer 3352, the via 3354, the memory structure 3356, the via 3360 and the metal layer 3362.

FIG. 38B shows a side cross-sectional view 3810 of the FIG. 37 structure illustrating a current path 3815 for programming and sensing of the capacitor 3701. The current path 3815 is from the metal layer 3370 to the via 3368, the electrode 3366, the selector device 3364, the metal layer 3352, the via 3350, the first epitaxial layer 3306, the vertical channel layer 3308, the second epitaxial layer 3314, the via 3324, the metal layer 3326 and the capacitor 3701.

FIG. 38C shows a side cross-sectional view 3820 of the FIG. 37 structure illustrating a current path 3825 for logic operation. The current path 3825 is from the metal layer 3370 to the via 3368, the electrode 3366, the selector device 3364, the metal layer 3352, the via 3350, the first epitaxial layer 3306, the vertical channel layer 3308, the second epitaxial layer 3314, the via 3324 and the metal layer 3326.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOSs), metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

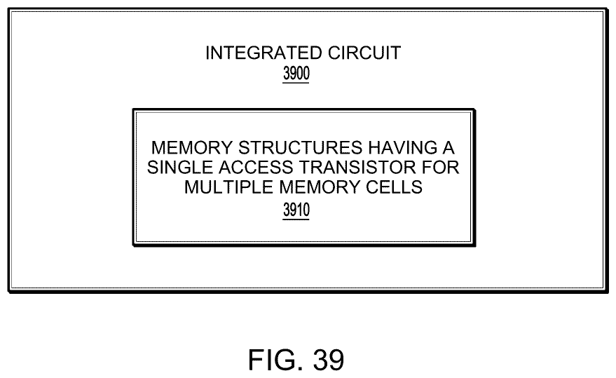

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 39 shows an example integrated circuit 3900 which includes one or more memory structures 3910 having a single access transistor for multiple memory cells.

In some embodiments, a semiconductor structure includes an access transistor, a first memory device connected to a first side of the access transistor, and a second memory device connected to a second side of the access transistor. The first memory device is connected to a first end of a first source/drain region of the access transistor and the second memory device is connected to a second end of the first source/drain region of the access transistor.

The access transistor may be a nanosheet transistor.

The semiconductor structure may further include a third memory device connected to the first side of the access transistor. The third memory device may be connected to a first end of a second source/drain region of the access transistor. The second source/drain region may include an isolating layer disposed between the first end of the second source/drain region and a second end of the second source/drain region. The access transistor may be a nanosheet transistor including two or more nanosheet channel layers, and the isolating layer may be disposed in vertically in the second source/drain region between a first one of the two or more nanosheet channel layers and a second one of the two or more nanosheet channel layers.

At least one of the first memory device and the second memory device may include a selector device providing a bipolar diode.

The first memory device and the second memory device may be resistive-based memory devices.

The first memory device may be a resistive-based memory device and the second memory device may be a capacitive-based memory device.

In some embodiments, a semiconductor structure includes an access transistor, a first memory device connected to a first side of the access transistor, and a second memory device connected to a second side of the access transistor. The first memory device is connected to a first source/drain region of the access transistor and the second memory device is connected to a second source/drain region of the access transistor.

The access transistor may be a vertical transistor. The first memory device may be connected to the first source/drain region at a first end of a vertical transport channel of the vertical transistor, and the second memory device may be connected to the second source/drain region at a second end of the vertical transport channel of the vertical transistor.

The first memory device in combination with the second memory device provides a multi-level memory cell.

At least one of the first memory device and the second memory device includes a selector device providing a bipolar diode.

The first memory device and the second memory device may be respective resistive-based memory devices.

The first memory device may be a resistive-based memory device and the second memory device may be a capacitive-based memory device.

In some embodiments, an integrated circuit includes a memory structure including an access transistor, a first memory device connected to a first side of the access transistor, and a second memory device connected to a second side of the access transistor. The first memory device and the second memory device are each connected to an end of at least one source/drain region of the access transistor.

The first memory device may be connected to a first end of a first source/drain region of the access transistor and the second memory device may be connected to a second end of the first source/drain region of the access transistor. The memory structure may further include a third memory device connected to the first side of the access transistor, the third memory device being connected to a first end of a second source/drain region of the access transistor.

The first memory device may be connected to a first source/drain region of the access transistor and the second memory device may be connected to a second source/drain region of the access transistor.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
an access transistor;
a first memory device connected to a first side of the access transistor; and
a second memory device connected to a second side of the access transistor;
wherein the first memory device is connected to a first end of a first source/drain region of the access transistor and the second memory device is connected to a second end of the first source/drain region of the access transistor.

2. The semiconductor structure of claim 1, wherein the access transistor comprises a nanosheet transistor.

3. The semiconductor structure of claim 1, further comprising a third memory device connected to the first side of the access transistor.

4. The semiconductor structure of claim 3, wherein the third memory device is connected to a first end of a second source/drain region of the access transistor.

5. The semiconductor structure of claim 4, wherein the second source/drain region comprises an isolating layer disposed between the first end of the second source/drain region and a second end of the second source/drain region.

6. The semiconductor structure of claim 5, wherein the access transistor comprises a nanosheet transistor comprising two or more nanosheet channel layers, and wherein the isolating layer is disposed in vertically in the second source/drain region between a first one of the two or more nanosheet channel layers and a second one of the two or more nanosheet channel layers.

7. The semiconductor structure of claim 1, wherein at least one of the first memory device and the second memory device comprises a selector device providing a bipolar diode.

8. The semiconductor structure of claim 1, wherein the first memory device and the second memory device comprise respective resistive-based memory devices.

9. The semiconductor structure of claim 1, wherein the first memory device comprises a resistive-based memory device and the second memory device comprises a capacitive-based memory device.

10. A semiconductor structure comprising:
an access transistor;
a first memory device connected to a first side of the access transistor; and
a second memory device connected to a second side of the access transistor;
wherein the first memory device is connected to a first source/drain region of the access transistor and the second memory device is connected to a second source/drain region of the access transistor.

11. The semiconductor structure of claim 10, wherein the access transistor comprises a vertical transistor.

12. The semiconductor structure of claim 11, wherein the first memory device is connected to the first source/drain region at a first end of a vertical transport channel of the vertical transistor, and wherein the second memory device is connected to the second source/drain region at a second end of the vertical transport channel of the vertical transistor.

13. The semiconductor structure of claim 10, wherein the first memory device in combination with the second memory device provides a multi-level memory cell.

14. The semiconductor structure of claim 10, wherein at least one of the first memory device and the second memory device comprises a selector device providing a bipolar diode.

15. The semiconductor structure of claim 10, wherein the first memory device and the second memory device comprise respective resistive-based memory devices.

16. The semiconductor structure of claim 10, wherein the first memory device comprises a resistive-based memory device and the second memory device comprises a capacitive-based memory device.

17. An integrated circuit comprising:
a memory structure comprising:
an access transistor;
a first memory device connected to a first side of the access transistor; and
a second memory device connected to a second side of the access transistor;
wherein the first memory device and the second memory device are each connected to an end of at least one source/drain region of the access transistor.

18. The integrated circuit of claim 17, wherein the first memory device is connected to a first end of a first source/drain region of the access transistor and the second memory device is connected to a second end of the first source/drain region of the access transistor.

19. The integrated circuit of claim 18, wherein the memory structure further comprises a third memory device connected to the first side of the access transistor, the third memory device being connected to a first end of a second source/drain region of the access transistor.

20. The integrated circuit of claim 17, wherein the first memory device is connected to a first source/drain region of the access transistor and the second memory device is connected to a second source/drain region of the access transistor.
